(19) United States
(12) Patent Application Publication
(10) Pub. No.: US 2025/0204141 A1
(43) Pub. Date: Jun. 19, 2025

(54) ORGANIC LIGHT-EMITTING COMPOSITE AND METHOD FOR PATTERNING ORGANIC LIGHT-EMITTING THIN FILM COMPRISING SAME, ORGANIC LIGHT-EMITTING COMPOSITION COMPRISING SAME, AND ORGANIC LIGHT-EMITTING DEVICE COMPRISING SAME

(71) Applicant: IUCF-HYU (INDUSTRY-UNIVERSITY COOPERATION FOUNDATION HANYANG UNIVERSITY), Seoul (KR)

(72) Inventors: Do Hwan KIM, Seoul (KR); Youngmin YOU, Seoul (KR); Bong Soo KIM, Ulsan (KR); Hyuk Min KWEON, Seoul (KR); Sang Jun PARK, Seoul (KR); Uk Jin JEONG, Seoul (KR); Seok Ran CHOI, Seoul (KR); Bo Ri Na HA, Seoul (KR); Yu Sung CHUN, Goyang-si Gyeonggi-do (KR); Da Yoon SONG, Seoul (KR); Ameen SHAHID, Ulsan (KR); Yu Chan HEO, Ulsan (KR)

(73) Assignee: IUCF-HYU (INDUSTRY-UNIVERSITY COOPERATION FOUNDATION HANYANG UNIVERSITY), Seoul (KR)

(21) Appl. No.: 18/843,922

(22) PCT Filed: Mar. 3, 2023
(86) PCT No.: PCT/KR2023/002902

§ 371 Date: Sep. 4, 2024

(30) Foreign Application Priority Data
Mar. 4, 2022 (KR) 10-2022-0028349
Mar. 29, 2022 (KR) 10-2022-0039023

(51) Int. Cl. H10K 50/12; H10K 71/20; H10K 85/30; H10K 85/40; H10K 85/60

(52) U.S. Cl. CPC H10K 50/12; H10K 71/233; H10K 85/342; H10K 85/40; H10K 85/6572; H10K 85/658

(57) ABSTRACT

Disclosed are an organic light-emitting composite, a high-resolution patterning method for an organic light-emitting thin film including the same, an organic light emitting composition including the organic light-emitting composite, and an organic light-emitting device including the organic light emitting composition. More particularly, the organic light-emitting composite includes a curable phosphorescent host; a curable phosphorescent dopant; and an organic silica precursor forming a silicone (—Si—O—Si—) network together with the curable phosphorescent host and the curable phosphorescent dopant, wherein the curable phosphorescent host and the curable phosphorescent dopant include a cross-linking functional group.

### TECHNICAL FIELD

The present disclosure relates to an organic light-emitting composite, a high-resolution patterning method for an organic light-emitting thin film including the same, an organic light emitting composition including the organic light-emitting composite, and an organic light-emitting device including the organic light emitting composition, and more particularly to a silicone (—Si—O—Si—)-integrated small-molecule organic light-emitting composite having a high-durability silicon (—Si—O—Si—) network, a patterning method for an organic light-emitting thin film including the composite, an organic light-emitting composition including the composite, and an organic light-emitting device including the organic light emitting composition.

### BACKGROUND ART

As realistic content and Real Metaverse (five senses augmentation technology) based on the construction of hyper-connected interactions between users and objects are rapidly emerging as next-generation IT content driving industries, visual-based hyper-realistic and immersive VR/AR/MR/XR devices that play a pivotal role in human senses and cognitive functions are receiving great attention.

Microdisplays, which are core elements responsible for the visual elements of hyper-realistic VR/AR/MR/XR technologies, serve as a medium to convey information to users by stimulating the most sensitive sense of vision among human senses, so their technical performance requirements are very high. Therefore, to provide users with an overwhelming sense of immersion and prevent adverse reactions (dizziness, vomiting) in the human body, a microdisplay that can implement i) an ultra-high-resolution RGB pattern of 3,000 ppi or more, ii) a fast response speed, iii) color purity similar to reality, and iv) low power consumption is required.

Organic light-emitting diodes (OLEDs) are gaining attention as next-generation displays that can effectively meet the performance requirements of ultra-realistic VR/AR/MR/XR microdisplays due to advantages such as i) excellent color reproducibility, ii) fast frame rates, iii) wide viewing angles, and iv) low power consumption. However, due to the inherent low durability of an organic light-emitting material, the implementation of ultra-high-resolution RGB patterns is extremely limited, so the demand for ultra-precision micropatterning technology of organic light-emitting diodes to solve this problem is rapidly increasing.

Various pattern technologies such as printing techniques, fine metal mask (FMM) patterns, orthogonal photolithography, and self-assembly patterns are being developed to implement ultra-high resolution patterns of organic luminants. However, there are still limitations in resolution, and there are various problems such as non-uniformity of patterns, degradation of luminescence performance depending on processes, and restrictions on multi-pattern processes for implementing RGB pixels based on solution processes. On the other hand, photolithography and dry etching are the most industrially optimized high-resolution pattern process technologies that can easily implement precise ultra-fine patterns with high efficiency. However, they require durability of materials that can withstand physical and chemical damage that is inevitably caused during the processes, so they have limitations that make it difficult to apply them to organic luminants.

For example, Korean Patent No. 2285162 discloses a technology for applying an iridium-type phosphorescent dopant material as a phosphorescent emitter in an organic light-emitting diode (OLED) device by introducing various cross-linking functional groups. An organic light-emitting layer can be formed by introducing a cross-linking functional group into an iridium-type phosphorescent dopant material, but since only chemical resistance to solvents of the organic light-emitting layer can be secured, there is a limitation in that photolithography and dry etching methods for implementing ultra-high-resolution patterns cannot be applied.

Korean Patent No. 1685071, which is a technology for forming a three-dimensional organic semiconductor compound in which a solubilized polymer semiconductor is orthogonally penetrated between the lattice structures of a gelled precursor by utilizing a polymer semiconductor and an organometallic precursor, enables high-resolution pattern implementation through a photolithography process by securing chemical resistance and etching resistance of the polymer semiconductor through a molecular structure in which the polymer semiconductor and precursor network are three-dimensionally entangled. However, since it is applied only to polymer semiconductor materials, not to small-molecule organic luminants currently adopted in the display industry, there is a limitation of low industrial applicability.

Zheng's literature describes a technology for fabricating high-density organic field-effect transistors by adding a photocrosslinker to polymer conductors and semiconductor materials and patterning all of electrodes, semiconductors, and insulators through a photolithography process and a wet etching method. Through the patterning process, high-resolution organic semiconductor patterns with a pattern size of approximately 2 μm and a pattern pitch of 5 μm can be implemented. However, this technology is limited to polymer semiconductor materials, and since the pattern is implemented through a wet etching process, not a dry etching process, there are limitations of low pattern density and uniformity.

Lee's literature relates to a technology to implement a polymer semiconductor (PTDPPSe-SiC4) with improved durability by introducing a siloxane (Si—O—Si) group into the side chain of a polymer semiconductor (PTDPPSe). Here, chemical resistance is secured through a cross-linking reaction between the siloxane groups introduced into the polymer side chain, and a polymer semiconductor pattern of about 2 μm can be implemented through a photolithography process and a dry etching method (CF4 gas). However, since it is limited to polymer semiconductor materials and not small-molecule organic luminants, there is a limitation of low industrial applicability.

Therefore, research on organic luminants based on small-molecule phosphorescent organic luminant (host and dopant) materials with improved etching resistance and chemical resistance so that they can be patterned through a photolithography process and a dry etching method is required.

### DISCLOSURE

### Technical Problem

Therefore, the present disclosure has been made in view of the above problems, and it is one object of the present disclosure to provide an organic light-emitting composite with a silicone (—Si—O—Si—) network which is based on a commercially available small-molecule phosphorescent organic luminant (host and dopant) material exhibiting high luminescence efficiency and excellent operating lifespan and which can be directly applied to photolithography and a dry etching method, which are established ultra-high-resolution pattern technologies, due to secured high durability (chemical resistance and etching resistance); a high-resolution patterning method for an organic light-emitting thin film including the organic light-emitting composite, an organic light-emitting composition including the organic light-emitting composite, and an organic light-emitting device including the organic light emitting composition.

It is another object of the present disclosure to provide an organic light-emitting composite capable of simultaneously increasing chemical resistance and etching resistance without deteriorating the optoelectronic properties by implementing a silicone (—Si—O—Si—) network by a simultaneous curing reaction or cross-curing reaction between the small-molecule phosphorescent organic luminant (the curable phosphorescent host and the curable phosphorescent dopant) and organic silica precursor into which cross-linking functional groups have been introduced, a high-resolution patterning method for an organic light-emitting thin film including the organic light-emitting composite, an organic light emitting composition including the organic light-emitting composite, and an organic light-emitting device including the organic light emitting composition.

### Technical Solution

In accordance with an aspect of the present disclosure, the above and other objects can be accomplished by the provision of an organic light-emitting composite, including: a curable phosphorescent host; a curable phosphorescent dopant; and an organic silica precursor forming a silicone (—Si—O—Si—) network together with the curable phosphorescent host and the curable phosphorescent dopant, wherein the curable phosphorescent host and the curable phosphorescent dopant include a cross-linking functional group.

The silicone (—Si—O—Si—) network may be a silicone (—Si—O—Si—)-integrated Single Phase Network (SPN), and the silicone (—Si—O—Si—)-integrated SPN may be formed by a simultaneous crosslinking reaction among the curable phosphorescent host, the curable phosphorescent dopant and the organic silica precursor.

The silicone (—Si—O—Si—) network may be a silicone (—Si—O—Si—)-integrated Interpenetrating Polymer Network (IPN), and the silicone (—Si—O—Si—)-integrated IPN may be formed by a simultaneous crosslinking reaction between the curable phosphorescent host and the curable phosphorescent dopant and a selective crosslinking reaction between the organic silica precursor.

The cross-linking functional group may include at least one of a vinyl group, a vinyl group derivative, an oxetane group, a boronic acid group, trifluoro vinyl ether, benzocyclobutene and epoxide.

The cross-linking functional group may include a functional group represented by one of Formulas 4 to 9 below:

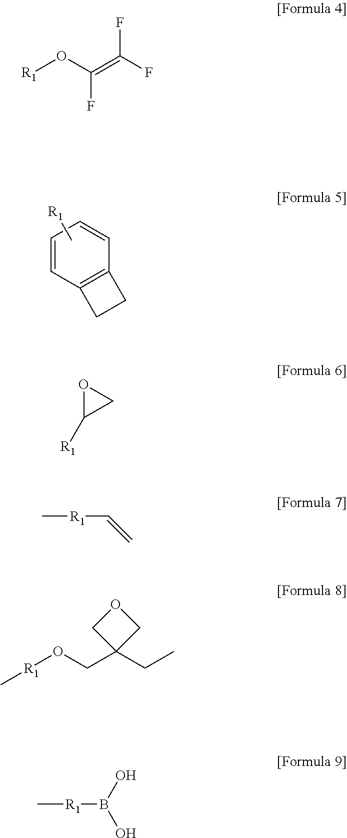

(in Formulas 4 to 9, R₁ each independently includes one of a hydrogen, a heavy hydrogen, a cyano group, a halogen group, an amino group, a thiol group, a hydroxy group, a nitro group, a carbonyl group, an ether group, a silane group, a siloxane group, a substituted or unsubstituted alkyl group having 1 to 20 carbon atoms, a substituted or unsubstituted cycloalkyl group having 3 to 20 carbon atoms, a substituted or unsubstituted alkenyl group having 2 to 20 carbon atoms, a substituted or unsubstituted alkynyl group having 2 to 20 carbon atoms, a halogenated alkyl group having 1 to 20 carbon atoms, a substituted or unsubstituted fluorenyl group, a substituted or unsubstituted aryl group having 6 to 30 carbon atoms, a substituted or unsubstituted aryloxy group having 6 to 30 carbon atoms, a substituted or unsubstituted heteroaryl group having 2 to 30 carbon atoms, a substituted or unsubstituted alkoxy group having 1 to 20 carbon atoms, a substituted or unsubstituted alkylsilyl group having 1 to 20 carbon atoms, a substituted or unsubstituted arylsilyl group having 6 to 30 carbon atoms, a substituted or unsubstituted arylalkyl group having 7 to 30 carbon atoms, a substituted or unsubstituted alkenyloxyl group having 2 to 30 carbon atoms, a substituted or unsubstituted aryl group having 8 to 30 carbon atoms alkenylaryl group, a substituted or unsubstituted arylalkoxy group having 7 to 30 carbon atoms, a substituted or unsubstituted arylalkenyl group having 8 to 30 carbon atoms and a substituted or unsubstituted alkoxycarbonyl group having 2 to 20 carbon atoms.)

The curable phosphorescent dopant may be a metal complex compound to which the cross-linking functional group has been bonded, and the metal complex compound may include at least one metal of iridium (Ir), platinum (Pt), osmium (Os), gold (Au), titanium (Ti), zirconium (Zr), hafnium (Hf), euroform (Eu), terbium (Tb), palladium (Pd) and thallium (Tm).

The curable phosphorescent dopant may include a compound represented by one of Formulas 10 and 11 below:

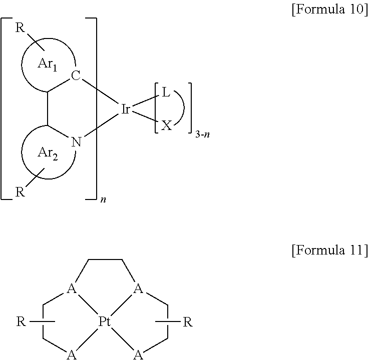

(in Formulas 10 and 11, n is 2 or 3, Ar₁ and Ar₂ are each at least one of a negatively charged and neutrally independently substituted or unsubstituted aryl group having 6 to 30 carbon atoms, a substituted or unsubstituted fluorenyl group and a substituted or unsubstituted heteroaryl group having 2 to 30 carbon atoms, L-X is a negatively charged di-coordinate ligand, R is a cross-linking functional group, and A each independently includes at least one of a substituted or unsubstituted aryl group having 6 to 30 carbon atoms, a substituted or unsubstituted fluorenyl group and a substituted or unsubstituted heteroaryl group having 2 to 30 carbon atoms.)

Luminescence intensity and charge lifespan of the organic light-emitting composite may be controlled depending upon a content of the curable phosphorescent dopant.

A content of the curable phosphorescent dopant may be 0.5% by weight to 20% by weight based on the organic light-emitting composite.

The curable phosphorescent host may be a host compound to which the cross-linking functional group has been bonded, and the host compound may include at least one of a carbazole-based compound, an anthracene-based compound, a fluorene-based compound, a triarylamine-based compound, a dibenzofuran-based compound, a dibenzothiophene-based compound, a dibenzosilole-based compound, a triazine-based compound, a triazole-based compound, an imidazole-based compound, an oxazine-based compound, an arylamine-based compound, a hydrazone-based compound, a stilbene-based compound, a starburst-based compound, an oxadiazole-based compound, a phosphine oxide-based compound, a bipyrimidine-based compound, a silane-based compound and a carboline-based compound.

The curable phosphorescent host may include a compound represented by one of Formulas 1 to 3 below:

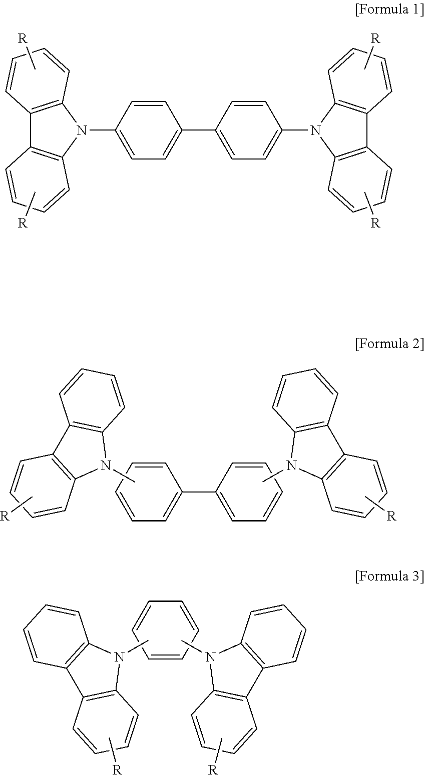

(in Formulas 1 to 3, R is a cross-linking functional group.)

The organic silica precursor may include a compound represented by one of Formulas 12 to 22 below:

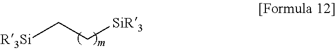

(in Formula 12, R′ includes one to three halogen elements or one to three alkoxy (—O—(CH₂)ₓ—CH₃, where X is an integer of 0 to 8.), and m is an integer of 0 to 20.)

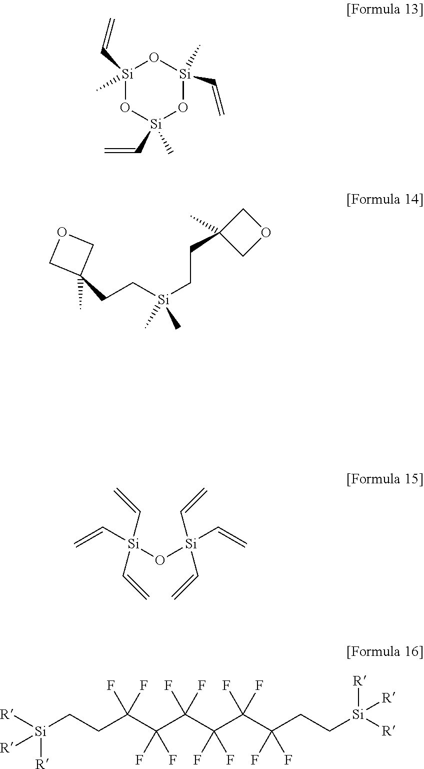

(in Formula 16, R′ includes one to three halogen elements or one to three alkoxy (—O—(CH₂)ₓ—CH₃, where X is an integer of 0 to 8.)

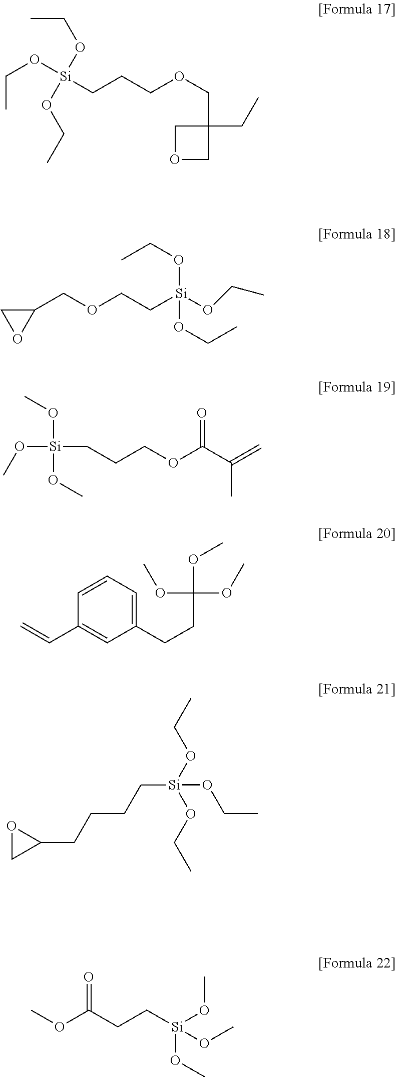

In accordance with another aspect of the present disclosure, provided is a patterning method for an organic light-emitting thin film, the patterning method including: forming an organic light-emitting thin film including the organic light-emitting composite according to claims 1 to 12 on a substrate; forming a photoresist on the organic light-emitting thin film; patterning the photoresist to form a photoresist pattern; dry-etching the organic light-emitting thin film using the photoresist pattern as an etching mask to form an organic light-emitting pattern; and removing the photoresist pattern.

The organic light-emitting composite may include a silicone (—Si—O—Si—) network, wherein the silicone (—Si—O—Si—) network is one of a silicone (—Si—O—Si—)-integrated Single Phase Network (SPN) and a silicone (—Si—O—Si—)-integrated Interpenetrating Polymer Network (IPN).

In the dry-etching, the organic light-emitting thin film may be formed as a non-volatile blocking layer on a side surface of the organic light-emitting pattern by a silicone (—Si—O—Si—) network of the organic light-emitting composite.

The non-volatile blocking layer may include at least one of SixOy and SixOyFz (x, y and z are an integer of 1 to 4).

The organic light-emitting pattern may have a size of 10 nm to 1000 μm.

In accordance with still another aspect of the present disclosure, there is provided an organic light-emitting device, including: a first electrode; a second electrode; and an organic light-emitting layer formed between the first electrode and the second electrode and including the organic light-emitting composite according to one of claims 1 to 12.

The organic light-emitting layer may include at least one of a red organic light-emitting pattern, a green organic light-emitting pattern and a blue organic light-emitting pattern.

In accordance with yet another aspect of the present disclosure, provided is an organic light-emitting composition, including: a curable phosphorescent host; a curable phosphorescent dopant; and an organic silica precursor.

The organic light-emitting composition may include: 80% by weight to 99.5% by weight of the curable phosphorescent host, and 0.5% by weight to 20% by weight of the curable phosphorescent dopant.

The organic light-emitting composition may include 1.9% by weight to 7.4% by weight of the organic silica precursor relative to a weight of the curable phosphorescent host.

### Advantageous Effects

In accordance with an embodiment of the present disclosure, the present disclosure can provide an organic light-emitting composite with a silicone (—Si—O—Si—) network which is based on a commercially available small-molecule phosphorescent organic luminant (host and dopant) material exhibiting high luminescence efficiency and excellent operating lifespan and which can be directly applied to photolithography and a dry etching method, which are established ultra-high-resolution pattern technologies, due to secured high durability (chemical resistance and etching resistance); a patterning method for an organic light-emitting thin film including the organic light-emitting composite, an organic light-emitting composition including the organic light-emitting composite, and an organic light-emitting device including the organic light emitting composition.

In particular, an embodiment of the present disclosure can provide an organic light-emitting composite capable of simultaneously increasing chemical resistance and etching resistance without deteriorating the optoelectronic properties by implementing a silicone (—Si—O—Si—) network by a simultaneous curing reaction or cross-curing reaction between the small-molecule phosphorescent organic luminant (the curable phosphorescent host and the curable phosphorescent dopant) and organic silica precursor into which cross-linking functional groups have been introduced, a patterning method for an organic light-emitting thin film including the organic light-emitting composite, an organic light emitting composition including the organic light-emitting composite, and an organic light-emitting device including the organic light emitting composition.

### BRIEF DESCRIPTION OF DRAWINGS

FIG. 1A is a schematic diagram illustrating an organic light-emitting composite according to an embodiment of the present disclosure.

FIG. 1B is a schematic diagram illustrating an organic silica precursor included in the organic light-emitting composite according to an embodiment of the present disclosure.

FIG. 2 is a schematic diagram illustrating a patterning method for an organic light-emitting thin film according to an embodiment of the present disclosure.

FIG. 3 illustrates a schematic diagram for comparing an existing etching process for an organic light-emitting thin film with a dry-etching process of the patterning method for an organic light-emitting composite thin film according to an embodiment of the present disclosure.

FIG. 4 illustrates the sectional view of an organic light-emitting device according to an embodiment of the present disclosure.

FIG. 5 is a graph illustrating the result of ¹HNMR analysis of the phosphorescent host (CBP-[B(OH)₂]₂, into which the boronic acid cross-linking functional group has been introduced, according to Example 1-1.

FIG. 6 is a graph illustrating the result of ¹HNMR analysis of the phosphorescent dopant (Ir[pyp-B(OH)₂]₃, into which the boronic acid cross-linking functional group has been introduced, according to Example 1-2.

FIG. 7 is a graph illustrating the luminescence intensity of the phosphorescent host (CBP-[B(OH)₂]₂, into which the boronic acid cross-linking functional group has been introduced, dependent upon the content of the phosphorescent dopant (Ir[pyp-B(OH)₂]₃ into which the boronic acid cross-linking functional group has been introduced.

FIG. 8 is a graph illustrating the charge lifespan of the phosphorescent host (CBP-[B(OH)₂]₂, into which the boronic acid cross-linking functional group has been introduced, dependent upon the content of the phosphorescent dopant (Ir[pyp-B(OH)₂]₃ into which the boronic acid cross-linking functional group has been introduced.

FIG. 9 is a graph illustrating the result of ¹HNMR analysis of the phosphorescent host (CBP-MOVB₂) according to Example 2-1 into which the vinyl cross-linking functional group has been introduced.

FIG. 10 is a graph illustrating the result of ¹HNMR analysis of the phosphorescent dopant (Ir(ppy)₃-MOVB₃) according to Example 2-2 into which the vinyl cross-linking functional group has been introduced.

FIG. 11 is a graph illustrating the FT-IR and thin film chemical resistance analysis results for the crosslinking reaction of the curable phosphorescent host (CBP-MOVB₂), into which the vinyl cross-linking functional group has been introduced, according to Example 2-1 and the phosphorescent dopant (Ir(ppy)₃-MOVB₃), into which the vinyl cross-linking functional group has been introduced, according to Example 2-2.

FIG. 12 illustrates a schematic diagram of the organic light-emitting composite having the silicone (—Si—O—Si—)-integrated IPN including the curable phosphorescent host (CBP-MOVB₂), into which the vinyl cross-linking functional group has been introduced, according to Example 2-1, the phosphorescent dopant (Ir(ppy)₃-MOVB₃), into which the vinyl cross-linking functional group has been introduced, according to Example 2-2 and an organic silica precursor (1,8-bis(trichlorosilyl)octane), and the FT-IR result of a silicone (—Si—O—Si—) network formation reaction.

FIG. 13 illustrates the optoelectronic property analysis results, dependent upon the content of the organic silica precursor, of the organic light-emitting composite according to FIG. 12.

FIG. 14 illustrates chemical resistance and etching resistance evaluation results of the organic light-emitting thin film including the organic light-emitting composite according to FIG. 12.

FIG. 15 illustrates analysis results of the luminescence characteristics of an OLED device using the organic light-emitting composite according to FIG. 12 as a light-emitting layer.

### BEST MODE

The present disclosure will now be described more fully with reference to the accompanying drawings and contents disclosed in the drawings. However, the present disclosure should not be construed as limited to the exemplary embodiments described herein.

The terms used in the present specification are used to explain a specific exemplary embodiment and not to limit the present inventive concept. Thus, the expression of singularity in the present specification includes the expression of plurality unless clearly specified otherwise in context. It will be further understood that the terms “comprise” and/or “comprising”, when used in this specification, specify the presence of stated components, steps, operations, and/or elements, but do not preclude the presence or addition of one or more other components, steps, operations, and/or elements thereof.

It should not be understood that arbitrary aspects or designs disclosed in “embodiments”, “examples”, “aspects”, etc. used in the specification are more satisfactory or advantageous than other aspects or designs.

In addition, the expression “or” means “inclusive or” rather than “exclusive or”. That is, unless mentioned otherwise or clearly inferred from context, the expression “x uses a or b” means any one of natural inclusive permutations.

In addition, as used in the description of the disclosure and the appended claims, the singular form “a” or “an” is intended to include the plural forms as well, unless context clearly indicates otherwise.

Although terms used in the specification are selected from terms generally used in related technical fields, other terms may be used according to technical development and/or due to changes, practices, priorities of technicians, etc. Therefore, it should not be understood that terms used below limit the technical spirit of the present disclosure, and it should be understood that the terms are exemplified to describe embodiments of the present disclosure.

Also, some of the terms used herein may be arbitrarily chosen by the present applicant. In this case, these terms are defined in detail below. Accordingly, the specific terms used herein should be understood based on the unique meanings thereof and the whole context of the present disclosure.

Meanwhile, terms such as “first” and “second” are used herein merely to describe a variety of constituent elements, but the constituent elements are not limited by the terms. The terms are used only for the purpose of distinguishing one constituent element from another constituent element.

In addition, when an element such as a layer, a film, a region, and a constituent is referred to as being “on” another element, the element can be directly on another element or an intervening element can be present.

Unless defined otherwise, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In addition, in the following description of the present disclosure, a detailed description of known functions and configurations incorporated herein will be omitted when it may make the subject matter of the present disclosure unclear. The terms used in the specification are defined in consideration of functions used in the present disclosure, and can be changed according to the intent or conventionally used methods of clients, operators, and users. Accordingly, definitions of the terms should be understood on the basis of the entire description of the present specification.

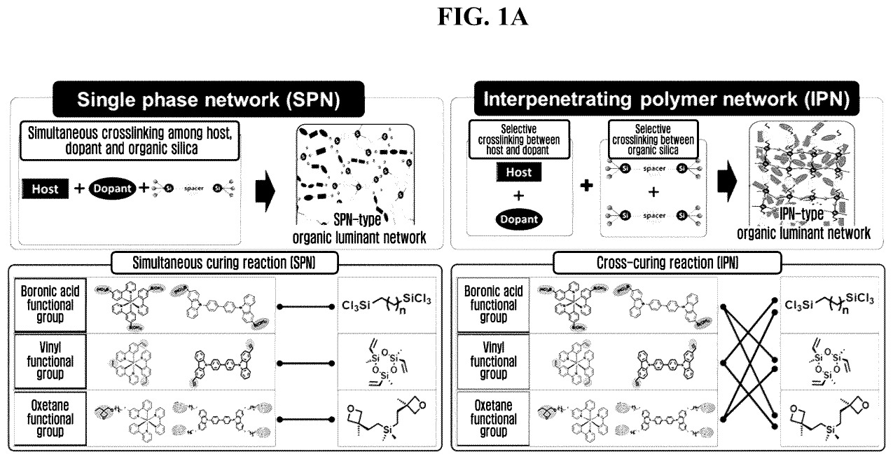

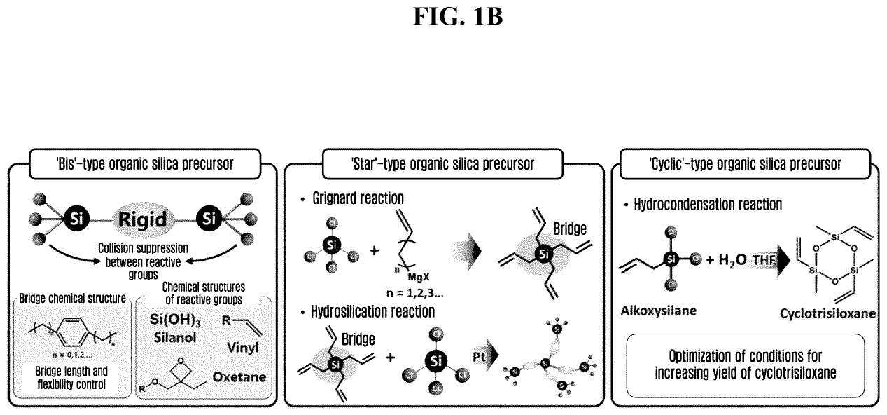

FIG. 1a is a schematic diagram illustrating an organic light-emitting composite according to an embodiment of the present disclosure, and FIG. 1b is a schematic diagram illustrating an organic silica precursor included in the organic light-emitting composite according to an embodiment of the present disclosure.

The organic light-emitting composite according to an embodiment of the present disclosure includes a curable phosphorescent host, a curable phosphorescent dopant and an organic silica precursor. The curable phosphorescent host and the curable phosphorescent dopant include a cross-linking functional group, and silicone (—Si—O—Si—)-integrated SPN or IPN may be formed through a simultaneous curing reaction or cross-curing reaction between the cross-linking functional groups of the curable phosphorescent host and curable phosphorescent dopant and an organic silica precursor.

Accordingly, the organic light-emitting composite according to an embodiment of the present disclosure may secure high durability (chemical resistance and etching resistance) by introducing a silicone (—Si—O—Si—) network to a commercially available small-molecule phosphorescent organic luminant (a curable phosphorescent host and a curable phosphorescent dopant) material showing high luminescence efficiency and excellent operating lifespan, thereby implementing an ultra-fine pattern through direct application of established ultra-high-resolution pattern technologies such as general-purpose photolithography and dry etching.

Hereinafter, each component of the organic light-emitting composite according to an embodiment of the present disclosure will be described in more detail.

The organic light-emitting composite according to an embodiment of the present disclosure includes a curable phosphorescent host including a cross-linking functional group.

A curable phosphorescent host is a host compound having a cross-linking functional group bonded thereto. The host compound may include at least one of a carbazole-based compound, an anthracene-based compound, a fluorene-based compound, a triarylamine-based compound, a dibenzofuran-based compound, a dibenzothiophene-based compound, a dibenzosilole-based compound, a triazine-based compound, a triazole-based compound, an imidazole-based compound, an oxazine-based compound, an arylamine-based compound, a hydrazone-based compound, a stilbene-based compound, a starburst-based compound, an oxadiazole-based compound, a phosphine oxide-based compound, a bipyrimidine-based compound, a silane-based compound and a carboline-based compound.

As the cross-linking functional group is bonded to a host compound, the curable phosphorescent host is crosslinked with at least one of the curable phosphorescent dopant and the organic silica precursor by a curing reaction, thereby forming a silicone (—Si—O—Si—) network.

The bonding position of the cross-linking functional group of the host compound is not particularly limited.

For example, the curable phosphorescent host may include a compound represented by one of Formulas 1 to 3 below:

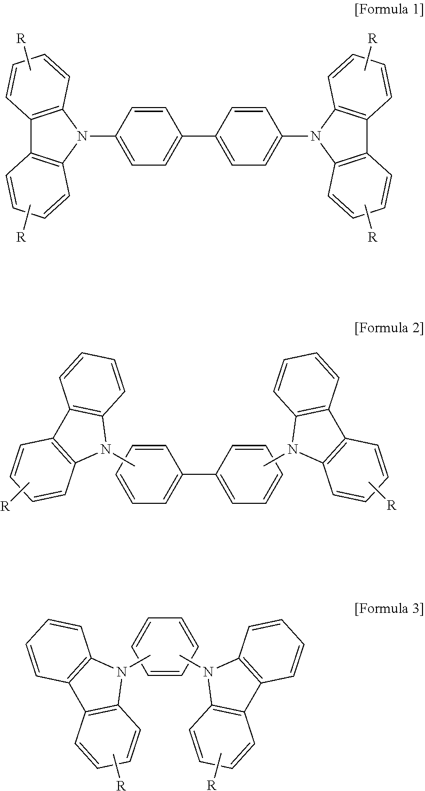

(In Formulas 1 to 3, R is a cross-linking functional group.)

Preferably, the curable phosphorescent host may include an aryl amine-based organic compound having a lower triplet energy level than a curable phosphorescent dopant.

The cross-linking functional group may include at least one of a vinyl group, a vinyl group derivative, an oxetane group, a boronic acid group, trifluoro vinyl ether, benzocyclobutene and epoxide. For example, the vinyl group derivative may include a vinyl group, a styrene group, etc.

Preferably, the cross-linking functional group may include a functional group represented by one of Formulas 4 to 9 below:

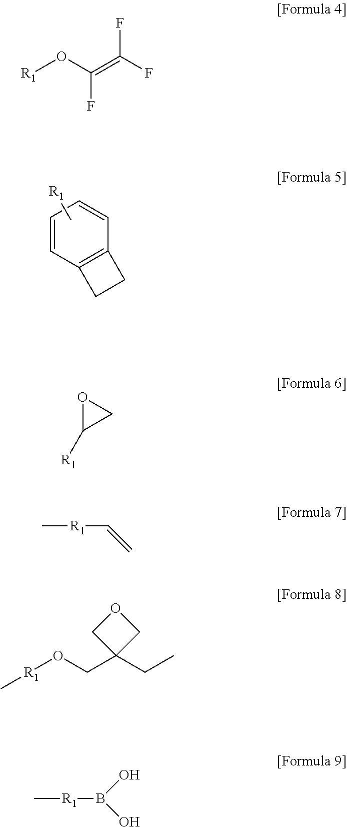

In Formulas 4 to 9, R₁ may each independently include one of a hydrogen, a heavy hydrogen, a cyano group, a halogen group, an amino group, a thiol group, a hydroxy group, a nitro group, a carbonyl group, an ether group, a silane group, a siloxane group, a substituted or unsubstituted alkyl group having 1 to 20 carbon atoms, a substituted or unsubstituted cycloalkyl group having 3 to 20 carbon atoms, a substituted or unsubstituted alkenyl group having 2 to 20 carbon atoms, a substituted or unsubstituted alkynyl group having 2 to 20 carbon atoms, a halogenated alkyl group having 1 to 20 carbon atoms, a substituted or unsubstituted fluorenyl group, a substituted or unsubstituted aryl group having 6 to 30 carbon atoms, a substituted or unsubstituted aryloxy group having 6 to 30 carbon atoms, a substituted or unsubstituted heteroaryl group having 2 to 30 carbon atoms, a substituted or unsubstituted alkoxy group having 1 to 20 carbon atoms, a substituted or unsubstituted alkylsilyl group having 1 to 20 carbon atoms, a substituted or unsubstituted arylsilyl group having 6 to 30 carbon atoms, a substituted or unsubstituted arylalkyl group having 7 to 30 carbon atoms, a substituted or unsubstituted alkenyloxyl group having 2 to 30 carbon atoms, a substituted or unsubstituted aryl group having 8 to 30 carbon atoms alkenylaryl group, a substituted or unsubstituted arylalkoxy group having 7 to 30 carbon atoms, a substituted or unsubstituted arylalkenyl group having 8 to 30 carbon atoms and a substituted or unsubstituted alkoxycarbonyl group having 2 to 20 carbon atoms.

According to an embodiment, the cross-linking functional group may include, without limitation, a functional group that undergoes a spontaneous polymerization reaction upon stimulation by heat and light irradiation.

The organic light-emitting composite according to an embodiment of the present disclosure includes a curable phosphorescent dopant including a cross-linking functional group.

The curable phosphorescent dopant is a metal complex compound having a cross-linking functional group bonded thereto. The metal complex compound may include at least one metal of iridium (Ir), platinum (Pt), osmium (Os), gold (Au), titanium (Ti), zirconium (Zr), hafnium (Hf), euroform (Eu), terbium (Tb), palladium (Pd) and thallium (Tm).

Preferably, the curable phosphorescent dopant may include at least one of a six-coordinate cyclometallated iridium complex and a four-coordinate cyclometallated platinum complex.

As the cross-linking functional group is bonded to the dopant compound, the curable phosphorescent dopant is crosslinked with at least one of the curable phosphorescent host and the organic silica precursor by a curing reaction, thereby forming a silicone (—Si—O—Si—) network.

The position of the ligand of the curable phosphorescent dopant and the bonding position of the cross-linking functional group are not particularly limited.

For example, the curable phosphorescent dopant may include a compound represented by one of Formulas 10 and 11 below:

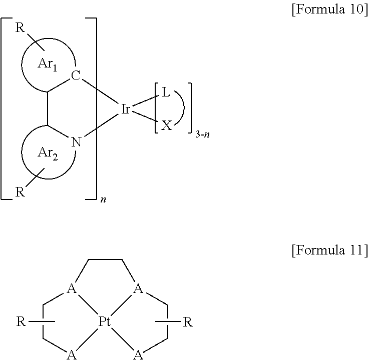

In Formulas 10 and 11, n may be 2 or 3, Ar₁ and Ar₂ may be each at least one of a negatively charged and neutrally independently substituted or unsubstituted aryl group having 6 to 30 carbon atoms, a substituted or unsubstituted fluorenyl group and a substituted or unsubstituted heteroaryl group having 2 to 30 carbon atoms, L-X may be a negatively charged di-coordinate ligand, R may be a cross-linking functional group, and A may each independently include at least one of a substituted or unsubstituted aryl group having 6 to 30 carbon atoms, a substituted or unsubstituted fluorenyl group and a substituted or unsubstituted heteroaryl group having 2 to 30 carbon atoms.

L-X may include an organic ligand selected from structures below, but is not limited thereto:

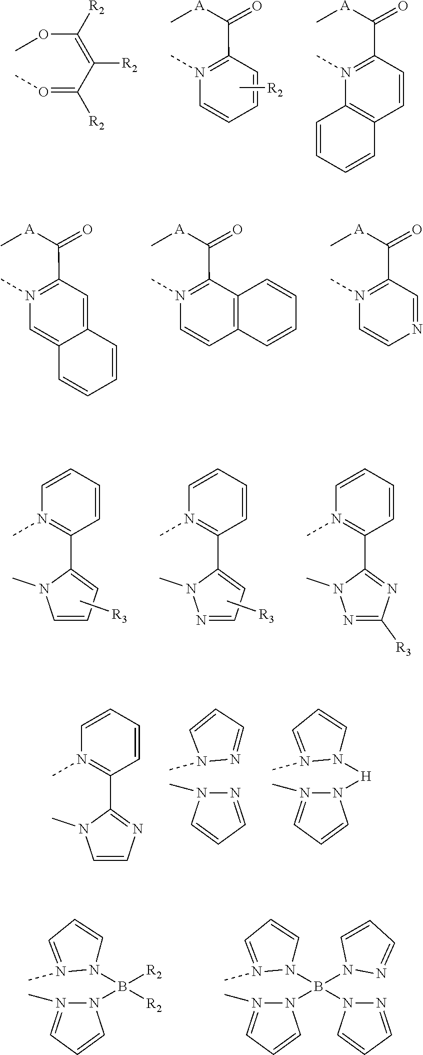

R₂ may each independently include at least one of a hydrogen, an alkyl group having 1 to 6 carbon atoms, a haloalkyl group having 1 to 6 carbon atoms and an aryl group having 6 to 12 carbon atoms among C1-C6 alkoxy, and R₃ may be CₐF2ₐ₊₁ (a is an integer from 1 to 10).

Preferably, L-X may include an organic ligand selected from structures below, but is not limited thereto:

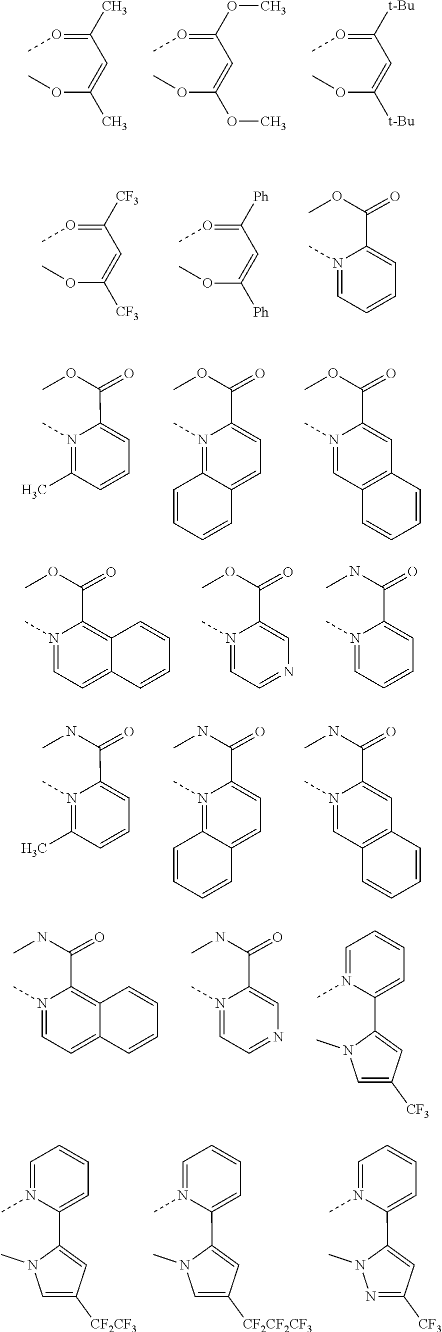

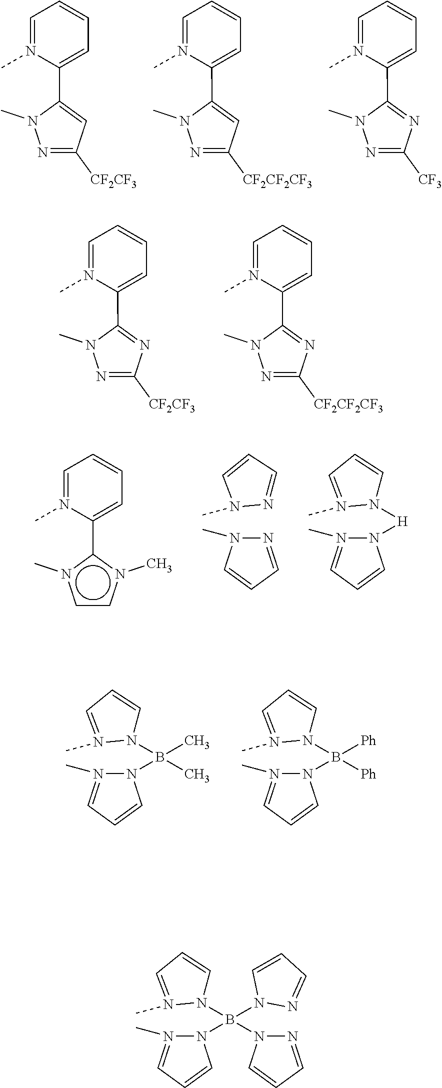

Preferably, A may be

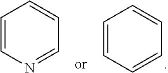

For example, Formula 10 may include a compound represented by Formula 10-1 below:

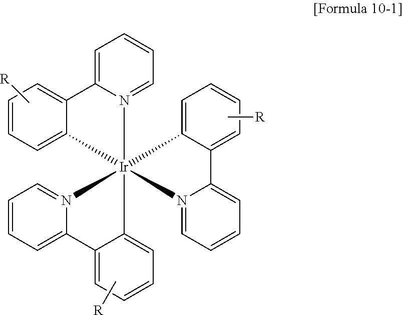

The cross-linking functional group may include the same components as described above.

Preferably, the curable phosphorescent dopant may be an iridium complex and platinum complex that form a silicone (—Si—O—Si—) network by mutual condensation reaction and addition reaction under heat and light irradiation stimulation.

According to an embodiment, the intensity and charge lifespan of the organic light-emitting composite according to an embodiment of the present disclosure may be controlled depending upon the content of the curable phosphorescent dopant luminescence.

For example, in the organic light-emitting composite according to an embodiment of the present disclosure, the luminescence intensity and charge lifespan of the curable phosphorescent host may decrease when the concentration of the curable phosphorescent dopant increases.

The content of the curable phosphorescent dopant may be 0.5% by weight to 20% by weight based on the organic light-emitting composite. When the curable phosphorescent dopant is contained at a concentration of less than 0.5% by weight, light may emit in peripheral layer other than the curable phosphorescent dopant in the device. When the content exceeds 20% by weight, there is a problem of emission quenching.

The organic light-emitting composite according to an embodiment of the present disclosure may be used for the formation of an organic light-emitting layer through a solution process by introducing various cross-linking functional groups to the curable phosphorescent host and the curable phosphorescent dopant, and may implement the chemical resistance of the organic light-emitting layer by irradiating heat or UV.

The organic light-emitting composite according to an embodiment of the present disclosure includes the curable phosphorescent host, the curable phosphorescent dopant, and an organic silica precursor forming a silicone (—Si—O—Si—) network.

The organic silica precursor may include at least one of a bis-type organic silica precursor, star-type organic silica precursor and cyclic-type organic silica precursor as shown in FIG. 1b.

In the organic light-emitting composite according to an embodiment of the present disclosure, the crosslinking reaction may proceed in the same manner if a curing functional group (e.g., a cross-linking functional group) introduced into the bis-type/star-type/cyclic-type organic silica precursor is the same, but an organic silica precursor may be appropriately selected depending upon the purpose.

More specifically, to effectively constitute a silicone (—Si—O—Si—) network by inducing a crosslinking reaction between a curable small-molecule organic luminant and an organic silica precursor or between precursor molecules, i) a crosslinking reaction in molecules of the organic silica precursor should be suppressed as much as possible, and ii) an effective silicone (—Si—O—Si—) network should be formed with a minimum content of an organic silica precursor as an insulator.

In the case of the bis-type organic silica precursor, a crosslinking reaction between organic silica precursor molecules may be effectively induced when the number of alkyl chains in the bridge chain is 5 or more or a rigid chemical structure such as benzene is introduced, and in the case of the star-type/cyclic-type organic silica precursor, a high-density silicone (—Si—O—Si—) network may be formed even with a minimum content because an organic silica precursor molecule contains three or more cross-linking functional group.

For example, the organic silica precursor may include a compound represented by one of Formulas 12 to 22 below:

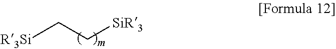

(In Formula 12, R′ includes one to three halogen elements or one to three alkoxy (—O—(CH₂)ₓ—CH₃, where X is an integer of 0 to 8.), and m is an integer of 0 to 20.)

(In Formula 16, R′ includes one to three halogen elements or one to three alkoxy (—O—(CH₂)ₓ—CH₃, where X is an integer of 0 to 8.)

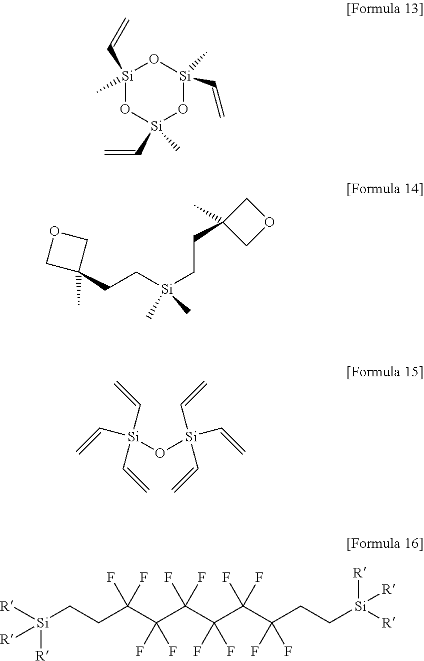

(In Formula 16, R′ includes one to three halogen elements or one to three alkoxy (—O—(CH₂)ₓ—CH₃, where X is an integer of 0 to 8.)

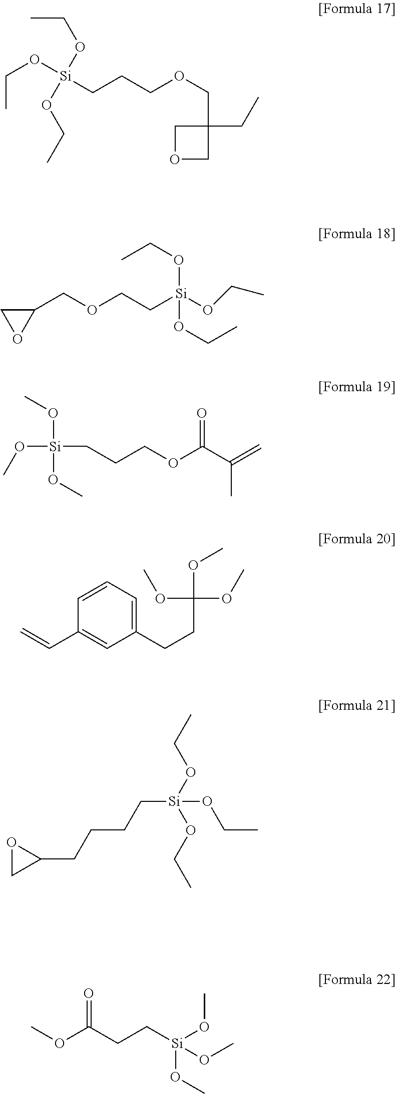

For example, Formula 12 may include a compound represented by Formula 12-1 below, and Formula 16 may include a compound represented by Formula 16-1 below:

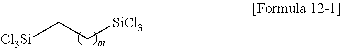

(In Formula 12-1, m is an integer of 0 to 20.)

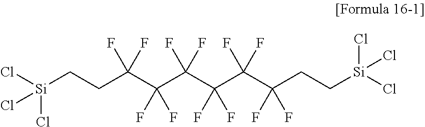 [SMILES: FC(F)(CC[Si](Cl)(Cl)Cl)C(F)(F)C(F)(F)C(F)(F)C(F)(F)C(F)(F)CC[Si](Cl)(Cl)Cl]

The organic silica precursor represented by Formula 15 is hexavinyldisiloxane, the organic silica Formula precursor represented by 16 is 1,6-bis(trichlorosilylethyl)dodecafluorohexane, the organic silica precursor represented by Formula 17 is 3-ethyl-3-[[3-(triethoxysilyl)propoxy]methyl]oxetane, the organic silica precursor represented by Formula 18 is (3-Glycidyloxypropyl)triethoxysilane, the organic silica precursor represented by Formula 19 is (3-trimethoxysilyl) propyl methacrylate, the organic silica precursor represented by Formula 20 is 2-(2-ethenylphenyl)ethyltrimethoxysilane, the organic silica precursor represented by Formula 21 is 5,6-epoxyhexyltriethoxysilane, and the organic silica precursor represented by Formula 22 is 2-(carbomethoxy)ethyltrimethoxysilane.

The organic light-emitting composite according to an embodiment of the present disclosure contains silicone (—Si—O—Si—) due to the organic silica precursor, thereby having a network including a structure represented by Formula 23 below:

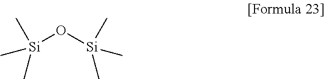

Accordingly, the silicone (—Si—O—Si—)-integrated network may be implemented through a simultaneous curing reaction or cross-curing reaction between the curable phosphorescent host and curable phosphorescent dopant, which are small-molecule organic luminants having a cross-linking functional group introduced thereinto, and the organic silica precursor, thereby simultaneously enhancing chemical resistance and etch resistance without deteriorating the optoelectronic properties.

Furthermore, the organic light-emitting composite according to an embodiment of the present disclosure may secure chemical resistance through the silicone (—Si—O—Si—)-integrated network, and since the material itself can form a non-volatile blocking layer through a chemical reaction between silicon molecules existing in the network and a dry etching gas, etch resistance may also be implemented at the same time.

Preferably, the network may be a silicone (—Si—O—Si—)-integrated Single Phase Network (SPN) or a silicone (—Si—O—Si—)-integrated Interpenetrating Polymer Network (IPN), and the above-described two silicone (—Si—O—Si—) networks may be formed by simultaneously or selectively curing depending upon cross-linking functional groups contained in the curable phosphorescent host, the curable phosphorescent dopant and the organic silica precursor.

That is, a highly durable (etch-resistant and chemical-resistant) organic light-emitting composite may be formed by controlling the mutual crosslinking reaction of the small-molecule organic luminant (the curable phosphorescent host and the curable phosphorescent dopant) and organic silica precursor where a cross-linking functional group has been introduced.

For example, when the curable phosphorescent host and the curable phosphorescent dopant include a first cross-linking functional group and the organic silica precursor includes a second cross-linking functional group, and if the first cross-linking functional group and the second cross-linking functional group are the same, the organic light-emitting composite according to an embodiment of the present disclosure may have a silicone (—Si—O—Si—)-integrated Single Phase Network (SPN), in which the curable phosphorescent host, the curable phosphorescent dopant and the organic silica precursor, through induction of a simultaneous curing reaction among the curable phosphorescent host, the curable phosphorescent dopant and the organic silica precursor.

Accordingly, the silicone (—Si—O—Si—)-integrated SPN may be formed by a simultaneous crosslinking reaction of the curable phosphorescent host, the curable phosphorescent dopant and the organic silica precursor.

For example, when the curable phosphorescent host and the curable phosphorescent dopant include the first cross-linking functional group, and the organic silica precursor includes the second cross-linking functional group, and if the first cross-linking functional group differs from the second cross-linking functional group, the organic light-emitting composite according to an embodiment of the present disclosure may have the silicone (—Si—O—Si—)-integrated Interpenetrating Polymer Network (IPN), in which the organic luminant network (the curable phosphorescent host—the curable phosphorescent dopant), and the silicone (—Si—O—Si—) network (the organic silica precursor) due to the organic silica precursor are physically entangled with each other, through independent induction of each of a simultaneous curing reaction between the curable phosphorescent host and curable phosphorescent dopant containing the same first cross-linking functional group and a selective curing reaction of the organic silica precursor.

Accordingly, the silicone (—Si—O—Si—)-integrated IPN may be formed by a simultaneous crosslinking reaction between the curable phosphorescent host and the curable phosphorescent dopant and the selective crosslinking reaction between the organic silica precursor.

In addition, when the organic light-emitting composite according to an embodiment of the present disclosure contains the organic silica precursor, the silicone (—Si—O—Si—) network may be formed even when the organic silica precursor is added in a small amount, so that high durability (chemical resistance and etching resistance) may be effectively improved. Accordingly, to manufacture the organic light-emitting composite according to an embodiment of the present disclosure, the structure (SPN), in which the silicone (—Si—O—Si—) network is directly connected to the organic luminant (the curable phosphorescent host-curable phosphorescent dopant), or the structure (IPN), in which the networks are physically entangled, may be flexibly selected depending upon the type of the cross-linking functional group.

Accordingly, since the structure (SPN), in which the silicone (—Si—O—Si—) network is directly connected to the organic luminant (the curable phosphorescent host-curable phosphorescent dopant) or the structure (IPN), in which the networks are physically entangled, may be selected depending upon the type of the cross-linking functional group to manufacture the organic light-emitting composite according to an embodiment of the present disclosure, various phosphorescent hosts, phosphorescent dopants (if a cross-linking functional group is bonded, phosphorescent host and phosphorescent dopant materials are not limited) and organic silica precursors may be used without limitation. Accordingly, the material group range is wide, so the material versatility is excellent.

In addition, the organic light-emitting composite according to an embodiment of the present disclosure may secure chemical resistance and etching resistance through a molecular structure in which a silicon (—Si—O—Si—)-integrated network is three-dimensionally entangled, thereby enabling high-resolution pattern implementation through a photolithography process.

The organic light-emitting composite according to an embodiment of the present disclosure may simultaneously enhance the chemical resistance and etching resistance of the small-molecule phosphorescent organic luminants (the curable phosphorescent host and the curable phosphorescent dopant), thereby enabling direct application of photolithography and dry etching, which are ultra-high-resolution pattern technologies, to an organic light-emitting material to implement an ultra-fine pattern at the level of several micrometers or less. Accordingly, the organic light-emitting composite may be effectively applied to microdisplays, head-up displays, and ultra-high-resolution OLEDs for mobile devices which require both excellent luminous efficiency and ultra-high resolution.

Therefore, since an OLED display that simultaneously secures high luminous efficiency and ultra-high resolution can be developed, the organic light-emitting composite according to an embodiment of the present disclosure may be effectively applied to ultra-realistic and immersive VR/AR/MR/XR content technology, visual interface technology for metaverse (augmented five senses), etc. Furthermore, the organic light-emitting composite according to an embodiment of the present disclosure is not limited to an organic luminant for OLEDs, but may be expanded to various electronic devices using small-molecule organic semiconductors, and thus may be applied to next-generation organic electronic device technologies such as high-resolution organic image sensors, neuromorphic organic electronic circuits, and flexible neurogrids.

In addition, the organic light-emitting composite according to an embodiment of the present disclosure may be provided in the form of a composition.

The organic light-emitting composition according to an embodiment of the present disclosure includes a curable phosphorescent host, a curable phosphorescent dopant and an organic silica precursor.

The organic light-emitting composition according to an embodiment of the present disclosure includes the same components as in the organic light-emitting composite according to an embodiment of the present disclosure, so a description of the same components is omitted.

The organic light-emitting composition according to an embodiment of the present disclosure may include 80% by weight to 99.5% by weight of the curable phosphorescent host and 0.5% by weight to 20% by weight of the curable phosphorescent dopant. The contents of the curable phosphorescent host and the curable phosphorescent dopant are not limited to the listed contents, and may be controlled depending upon the type of the cross-linking functional group.

In addition, the organic light-emitting composition according to an embodiment of the present disclosure may include 1.9% by weight to 7.4% by weight of the organic silica precursor compared to the weight of the curable phosphorescent host. When the organic silica precursor is included in an amount of less than 1.9% by weight, etching resistance may be reduced. On the other hand, when the organic silica precursor is included in an amount of greater than 7.4% by weight, the characteristics of an organic light-emitting device may be deteriorated due to the insulating properties of the organic silica precursor. However, the content of the organic silica precursor is not limited to the listed contents, and may be controlled depending upon the type of the cross-linking functional group.

For example, when including a vinyl group as a cross-linking functional group, the organic light-emitting composition may include 80% by weight to 99.5% by weight of the curable phosphorescent host compared to the organic light-emitting composition, and 0.5% by weight to 20% by weight of the curable phosphorescent dopant compared to the organic light-emitting composition. In addition, the organic light-emitting composition may include 1.9% by weight to 7.4% by weight of the organic silica precursor compared to the weight of the curable phosphorescent host.

The etching resistance of the organic light-emitting composition according to an embodiment of the present disclosure may be controlled depending upon the content of the organic silica precursor.

For example, since the number of silicone molecules per unit volume of the organic light-emitting composite thin film increases as the content of the organic silica precursor increases, the etching resistance may increase. However, since the characteristics of OLEDs may decrease with increasing content due to the insulating properties of the organic silica precursor, the content needs to be appropriately controlled.

In addition, the luminescence intensity and charge lifespan of the organic light-emitting composition according to an embodiment of the present disclosure may be controlled depending upon the content of the curable phosphorescent dopant.

For example, when the content of the curable phosphorescent dopant in the organic light-emitting composition according to an embodiment of the present disclosure increases, the luminescence intensity and charge lifespan of the curable phosphorescent dopant may be decreased due to a quenching phenomenon.

According to an embodiment, the organic light-emitting composition according to an embodiment of the present disclosure may further include a residual amount of an organic solvent.

The solvent is not particularly limited, but, for example, the solvent may include at least one of an alcohol-based solvent, a halogen-containing solvent, a hydrocarbon-based solvent, a ketone-based solvent, an ester-based solvent, and an amide-based solvent.

For example, the alcohol-based solvent may include at least one of methanol, ethanol, propan-1-ol, butan-1-ol, pentan-1-ol, hexan-1-ol, heptan-1-ol, octan-1-ol, nonan-1-ol, decan-1-ol, undecan-1-ol, dodecan-1-ol, tridecan-1-ol, tetradecan-1-ol, pentadecan-1-o, hexadecan-1-ol, heptadecan-1-ol, octadecan-1-ol, nonadecan-1-ol, eicosan-1-ol, hen-eicosan-1-ol, docosan-1-ol, tricosan-1-ol, tetracosan-1-ol, pentacosan-1-ol, hexacosan-1-ol, heptacosan-1-ol, octacosan-1-ol, nonacosan-1-ol, triacontan-1-ol, policosanol, 2-methyl: 2-methylpropan-1-ol, 3-methyl: 3-methylbutan-1-ol, propan-2-ol, butan-2-ol, pentan-2-ol, hexan-2-ol, heptan-2-ol, 2-methyl: 2-methylbutan-1-ol, cyclohexanol, 2-methyl: 2-methylpropan-2-ol, 2-mhylbutan-2-ol, 2-methylpentan-2-ol, 2-methylhexan-2-ol, 2-methylheptan-2-ol, and 3-methyl: 3-methylpentan-3-ol and 3-methyloctan-3-ol.

The halogen-containing solvent may include at least one of chlorobenzene, chloroform, tetrafluorodibromo ethylene, trichloroethylene, tetrachloroethylene, trifluorochloroethylene, 1,2,4-trichlorobenzene, carbon tetrachloride, dichloromethane and dichloroethane, dichlorobenzene.

The hydrocarbon-based solvent may include at least one of octane, nonane, decane, undecane, toluene, xylene, ethylbenzene, n-propylbenzene, iso-propylbenzene, n-propylbenzene, mesitylene, n-butylbenzene, sec-butylbenzene, 1-phenylpentane, 2-phenylpentane, 3-phenylpentane, henylcyclopentane, phenylcyclohexane, 2-ethylbiphenyl and 3-ethylbiphenyl.

The ether-based solvent may include at least one of 1,4-dioxane, 1,2-diethoxyethane, diethyleneglycoldimethylether, diethyleneglycoldiethylether, anisole, ethoxybenzene, 3-methylanisole and m-dimethoxybenzene.

The ketone-based solvent may include at least one of 2-hexanone, 3-hexanone, cyclohexanone, 2-heptanone, 3-heptanone, 4-heptanone and cycloheptanone.

The ester-based solvent may include at least one of butylacetate, butylpropionate, heptylbutyrate, propylenecarbonate, methylbenzoate, ethylbenzoate, 1-propylbenzoate and 1-1-butylbenzoate.

The amide-based solvent may include at least one of dimethylformamide, dimethylacetamide and N-methylpyrrolidone.

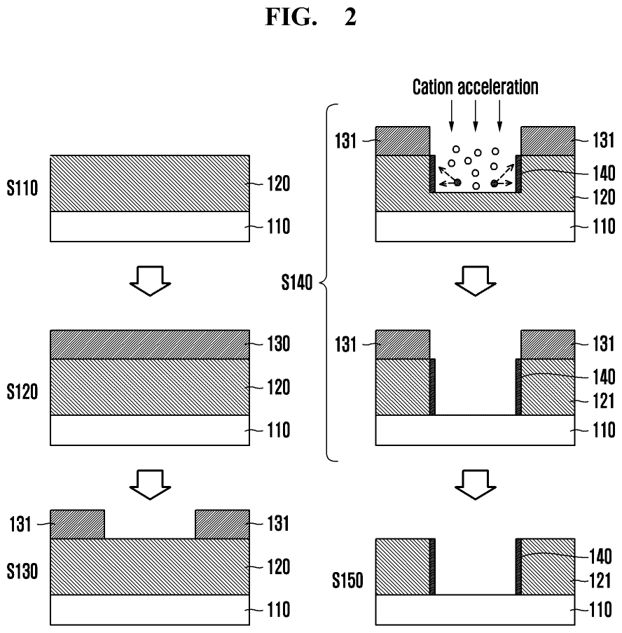

FIG. 2 is a schematic diagram illustrating a patterning method for an organic light-emitting thin film according to an embodiment of the present disclosure.

First, the patterning method for an organic light-emitting thin film according to an embodiment of the present disclosure includes a step (S110) of forming an organic light-emitting thin film 120 including the organic light-emitting composite according to an embodiment of the present disclosure on a substrate 110.

The substrate 110 may be an inorganic substrate or an organic substrate.

The inorganic substrate may include at least one of glass, quartz, Al₂₀₃, SiC, Si, GaAs and InP.

The organic substrate may include at least one of Kapton foil, polyethylene terephthalate (PET), polyimide (PI), polydimethylsiloxane (PDMS), polyethersulfone (PES), polyacrylate (PAR), polyetherimide (PEI), polyethylene naphthalate (PEN), polyethylene terephthalate (PET), polyphenylene sulfide (PPS), polyarylate, polycarbonate (PC), cellulose triacetate (CTA) and cellulose acetate propionate (CAP).

According to an embodiment, the patterning method for an organic light-emitting thin film according to an embodiment of the present disclosure may include a step of performing ultraviolet-ozone treatment to form a hydrophilic group on the surface of the substrate 110.

By the ultraviolet-ozone treatment, a hydrophilic group is formed on the surface of the substrate 110, thereby improving the surface adhesion between the substrate 110 and the organic light-emitting thin film 120 to be formed in a subsequent process.

The hydrophilic group may be at least one of a —OH group, a —OOH group and a —OO— group, and preferably, the hydrophilic group may be a —OH group.

The organic light-emitting thin film 120 may be formed by coating with a coating solution containing the organic light-emitting composite according to an embodiment of the present disclosure.

The coating solution may include an organic light-emitting composite and a solvent.

The organic light-emitting composite and the solvent include the same components as in the organic light-emitting composite according to an embodiment of the present disclosure that has been described with reference to FIGS. 1a and 1b, so a description of the same components is omitted.

The organic light-emitting composite includes a silicone (—Si—O—Si—) network. The silicone (—Si—O—Si—) network may be one of a silicone (—Si—O—Si—)-integrated Single Phase Network (SPN) and a silicone (—Si—O—Si—)-integrated Interpenetrating Polymer Network (IPN).

The organic light-emitting thin film 120 may be coated by at least one method of spin coating, flexible coating, roll coating, slit and spin coating, slit coating, spray coating, roll to roll, bar coating, dip coating, casting, die coating, blade coating, gravure coating, and doctor coating.

Next, according to the patterning method for an organic light-emitting thin film according to an embodiment of the present disclosure, a step (S120) of forming a photoresist 130 on the organic light-emitting thin film 120 is performed.

In step S120, the photoresist 130 may be formed by applying a photoresist solution on the organic light-emitting thin film 120, followed by heating and drying (prebaking) the photoresist solution-applied substrate 110, or drying the photoresist solution-applied substrate 110 under reduced pressure and then heating the same.

The substrate 110 applied with the photoresist 130 may be heated to evaporate volatile components such as a solvent. Here, the heating temperature may be relatively low 70 to 100° C., and the heating and drying (prebaking) may be performed at 110° C. for 2 minutes.

The photoresist 130 may be coated by at least one method of spin coating, flexible coating, roll coating, slit and spin coating, slit coating, spray coating, roll to roll, bar coating, dip coating, casting, die coating, blade coating, gravure coating, and doctor coating.

Next, according to the patterning method for an organic light-emitting thin film according to an embodiment of the present disclosure, a step (S130) of patterning the photoresist 130 to form a photoresist pattern 131 is performed.

In step S130, the photoresist pattern 131 may be formed by exposing the photoresist 130 using a mask having a target pattern engraved thereon, and then performing a development process for the exposed photoresist 130 using a developing solution. For example, exposure may be performed by irradiating ultraviolet rays using a mask for forming a target pattern. When ultraviolet rays are irradiated to the photoresist 130, the chemical structure of the photoresist part irradiated with ultraviolet rays changes, so that it may be easily dissolved in a developer.

Next, according to the patterning method for an organic light-emitting thin film according to an embodiment of the present disclosure, a step (S140) of dry-etching the organic light-emitting thin film 120 using the photoresist pattern 131 as an etching mask to form an organic light-emitting pattern 121.

The organic light-emitting pattern 121 may be formed by etching the organic light-emitting thin film 120 using an etching gas and washing the organic light-emitting thin film.

The etching gas may include at least one of CF₄, Cl₂, BCl₃, HCl, HBr, NF₃ and SF₆. According to an embodiment, the etching gas may be a mixed gas containing at least one of Ar, He, O₂, and H₂.

In particular, in the step (S140) of dry-etching the organic light-emitting thin film 120 using the photoresist pattern 131 as an etching mask to form an organic light-emitting pattern 121, the organic light-emitting thin film 120 is etched when the organic light-emitting thin film 120 is exposed to the etching gas, so that a non-volatile blocking layer 140 may be formed on a side surface of the organic light-emitting pattern 121 by the silicone (—Si—O—Si—) network of the organic light-emitting composite while the organic light-emitting pattern 121 is formed.

The non-volatile blocking layer 140 may include at least one of SixOy and SixOyFz (x, y and z are an integer of 1 to 4.).

For example, since the non-volatile blocking layer 140 is formed by a reaction between a material to be etched and an etching gas or a gas radical, the amount of chemical reaction may be controlled depending upon the material to be etched and the etching gas or the gas radical. For example, it may be SiO₂, but is not limited thereto.

More specifically, since the organic light-emitting thin film 120 may form the non-volatile blocking layer 140 by itself by a chemical reaction between the contained silicone (—Si—O—Si—) molecules and the dry-etching gas (e.g., Ar/O₂ or CF₄), it is possible to implement an anisotropic ultra-fine pattern based on photolithography and dry-etching.

For example, SixOy may be formed by a reaction between O* (radical) generated from O₂ gas and Si or Si—O(SiO+O*→SixOy or SiO+O*→SixOy), and SixOyFz may be formed by a reaction between F* (radical) generated from CF₄ gas and Si—O(Si—O+F*→SixOyFz).

Accordingly, the patterning method for an organic light-emitting thin film according to an embodiment of the present disclosure may implement a phosphorescent small-molecule organic light-emitting silicone (—Si—O—Si—) network (SPN & IPN) having both high luminous efficiency and high durability and, accordingly, implement an ultra-fine pattern through general photolithography and dry etching while maintaining the excellent luminescence characteristics of OLED.

That is, the patterning method for an organic light-emitting thin film according to an embodiment of the present disclosure is an ultra-high-resolution pattern process technology utilizing the photolithography-tailored organic light-emitting composite and the non-volatile blocking layer 140 and may be effectively applied not only to an ultra-high-resolution microdisplay for ultra-realistic and immersive VR/AR/MR/XR, but also to the implementation of a user-object visual interface for real metaverse (five-sense augmentation type) which is an aggregation of high-dimensional artificial sensory technologies.

Finally, the patterning method for an organic light-emitting thin film according to an embodiment of the present disclosure includes a step (S150) of removing the photoresist pattern 131.

In step S150, the photoresist pattern 130 is removed by a development process so that the organic light-emitting pattern 121 may be formed on the substrate 110.

The size (width) of the organic light-emitting pattern 121 may be from several hundred nanometers to several hundred micrometers. For example, the size of the organic light-emitting pattern 121 may be from 10 nm to 1000 μm, but is not limited thereto. The size of the organic light-emitting pattern 121 may be variously adjusted depending upon the size of an OLED display to be applied with the organic light-emitting pattern 121 and the purpose of use.

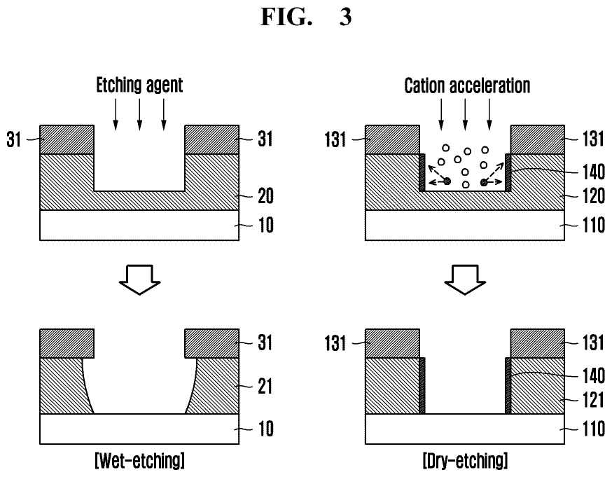

FIG. 3 illustrates a schematic diagram for comparing an existing etching process with a dry-etching process of the patterning method for an organic light-emitting thin film according to an embodiment of the present disclosure.

In the case of an existing technology that increases durability by introducing a cross-linking functional group to organic luminants, it is impossible to apply photolithography and dry-etching for implementing ultra-high-resolution patterns because only the chemical resistance of organic luminescent materials to a solvent can be secured.

In addition, cases of directly applying photolithography to organic electronic materials to implement high-resolution patterns have been reported, but they are limited to polymer materials, not low-molecular organic semiconductors with high industrial applicability, and since patterns are mainly implemented through a wet-etching process, not a dry-etching process, they have limitations of low pattern density and uniformity.

Referring to FIG. 3, in the existing case of patterning an organic light-emitting thin film 20 using a wet etching or dry etching process, an organic light-emitting pattern 21 is over-etched or a notch phenomenon occurs, and an overhang structure may be formed due to the use of this notch phenomenon.

Due to the notch phenomenon, cations generated during a dry-etching process, such as a plasma dry-etching process, accumulate (charge) on a substrate 10, and the plasma loses its straightness and bends to the side surface due to the accumulated cations, thereby forming an overhang structure in the lower region of the organic light-emitting thin film 20.

In the case of a wet-etching process, there is a limitation that the pattern density and uniformity are low because it is etched isotropically. In addition, over-etching may cause an undercut phenomenon in which an etched area spreads.

In the case of a dry-etching process, the vertical etching speed is faster due to anisotropy, but as the depth of the pattern being etched increases, the side surface direction is also etched at a lower speed, which limits the implementation of anisotropic patterns. As an example to solve the above problem, there is a Bosch process that enables etching in a high aspect ratio by alternately repeating the passivation process of artificially forming a blocking layer during the dry-etching process, and the etching process. However, the process has problems such as the scalloping effect that the side surface of a pattern is formed in a sawtooth shape, and a long process time.

Accordingly, there is a problem that the pattern accuracy, pattern density and uniformity of the organic light-emitting pattern 21 are lowered.

However, since the patterning method for an organic light-emitting thin film according to an embodiment of the present disclosure includes an organic light-emitting composite in which the organic light-emitting thin film 120 has the silicone (—Si—O—Si—)-integrated network, a non-volatile blocking layer 140 that reacts with an etching gas when dry-etching the organic light-emitting thin film 120 to protect the organic light-emitting pattern 121 on the side surface of the organic light-emitting pattern 121 is formed by itself, pattern accuracy, pattern density and uniformity may be improved.

Accordingly, the patterning method for an organic light-emitting thin film according to an embodiment of the present disclosure may implement a phosphorescent small-molecule organic light-emitting silicone (—Si—O—Si—) network (SPN & IPN) having both high luminous efficiency and high durability, thereby implementing an ultra-fine pattern through general photolithography and dry etching while maintaining the excellent luminescence characteristics of OLED.

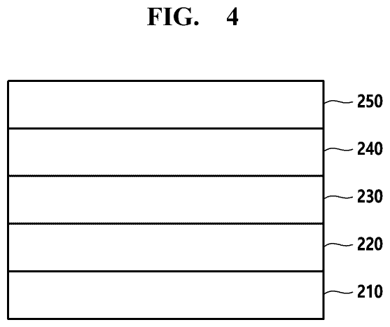

FIG. 4 illustrates the sectional view of an organic light-emitting device according to an embodiment of the present disclosure.

The organic light-emitting device according to an embodiment of the present disclosure includes a first electrode 210; a second electrode 250; and an organic light-emitting layer 230 formed between the first electrode 210 and the second electrode 250 and including the organic light-emitting composite according to an embodiment of the present disclosure.

The organic light-emitting device has a principle in which electrons and holes injected through a cathode and anode are recombined in the organic light-emitting layer 230, and when the exciton generated at this time falls to the ground state, visible light corresponding to the energy gap of the organic light-emitting layer 230 material is emitted. Depending upon how the organic light-emitting layer 230 is formed, a blue, green, or red light-emitting device may be implemented.

According to an embodiment, the first electrode 210 may be formed on a substrate, or the first electrode 210 may function as both an electrode and a substrate.

As a substrate, substrates used in general organic light-emitting devices may be used, but it is preferable to use a glass substrate or transparent plastic substrate that has excellent transparency, surface smoothness, ease of handling, and waterproofing.

The first electrode 210 may be patterned in pixel units to inject holes into the organic light-emitting layer 230. For example, the first electrode 210 may be an anode.

The first electrode 210 may be connected to one of source and drain electrodes of a thin film transistor and may serve to receive a driving current applied from the thin film transistor.

The first electrode 210 may be formed of known electrode materials used in organic light-emitting devices. Preferably, the first electrode 210 may include at least one of gold (Au), palladium (Pd), platinum (Pt), indium tin oxide (ITO), aluminum zinc oxide (AZO), fluorine tin oxide (FTO), indium zinc oxide (IZO), zinc oxide (ZnO), carbon nanotubes (CNT), graphene, polyethylenedioxythiophene:polystyrenesulfonate (PEDOT:PSS) and silver nanowires (AgNWs).

More preferably, the first electrode 210 may include indium tin oxide (ITO) which is a transparent electrode with a large work function to facilitate the injection of holes into the highest occupied molecular orbital (HOMO) level of the organic light-emitting layer 230.

The organic light-emitting device according to an embodiment of the present disclosure may include the second electrode 250 provided to opposite to the first electrode 210. For example, the second electrode 250 may be a cathode.

The second electrode 250 may be commonly connected to power supply voltage and may serve to inject electrons into the organic light-emitting layer 230.

The second electrode 250 may be formed of known electrode materials used in organic light-emitting devices, Preferably, the second electrode 250 may include at least one of lithium fluoride/aluminum (LiF/Al), aluminum (Al), silver (Ag), gold (Au), copper (Cu), palladium (Pd), platinum (Pt), magnesium (Mg), magnesium silver (Mg:Ag), ytterbium (Yb), magnesium (Mg), ytterbium (Yb), and calcium (Ca).

More preferably, as the second electrode 250, a metal electrode having a low work function for easy injection of electrons into the lowest unoccupied molecular orbital (LUMO) level of the organic light-emitting layer 230 and excellent internal reflectivity may be used. The second electrode 250 may include at least one of lithium fluoride/aluminum (LiF/Al), aluminum (Al), silver (Ag), copper (Cu), palladium (Pd), magnesium (Mg), magnesium silver (Mg:Ag) and ytterbium (Yb).

The first electrode 210 and the second electrode 250 are electrically separated from each other and provide power to an organic light-emitting device. In addition, the first electrode 210 and the second electrode 250 may reflect light generated from the organic light-emitting device to increase light efficiency, and may also serve to discharge heat generated from the organic light-emitting device to the outside.

The organic light-emitting layer 230 is a layer in which holes injected from the first electrode 210 and electrons injected from the second electrode 250 recombine to generate excitons, and the generated excitons change from an excited state to a ground state, emitting light. The organic light-emitting layer 230 may be composed of a single layer or multiple layers.

The organic light-emitting layer 230 includes the organic light-emitting layer 230 including the organic light-emitting composite according to an embodiment of the present disclosure.

Accordingly, the organic light-emitting layer 230 included in the organic light-emitting device according to an embodiment of the present disclosure may emit phosphorescence by triplet excitons.

Phosphorescence used as the organic light-emitting layer 230 may have a much higher quantum efficiency than fluorescence, thus increasing the efficiency of the organic light-emitting device.

In addition, the organic light-emitting layer 230 may improve the internal quantum efficiency by using a phosphorescent material that phosphoresces by triplet excitons, thereby increasing the efficiency of the organic light-emitting device.

The organic light-emitting composite according to an embodiment of the present disclosure includes the same components as those described in FIGS. 1A and 1B, so a description of the same components is omitted.

The organic light-emitting layer 230 may include at least one of a red organic light-emitting pattern, a green organic light-emitting pattern and a blue organic light-emitting pattern.

Accordingly, the organic light-emitting device according to an embodiment of the present disclosure may be an organic light-emitting device based on organic light-emitting complex patterns including at least two organic light-emitting layers among RGB, by forming at least two organic light-emitting layer patterns among RGB through a continuous solution process, a photolithography process, and a dry etching process.

More specifically, to implement RGB patterns through continuous photolithography and a dry etching method, a total of three photolithography processes are applied, so a pre-patterned preceding layer should have durability that can withstand the second and third photolithography processes. In this respect, the organic light-emitting device according to an embodiment of the present disclosure includes the organic light-emitting composite according to an embodiment of the present disclosure having excellent chemical resistance and etching resistance, so that at least two organic light-emitting layer patterns among RGB may be formed.

Accordingly, to implement RGB patterns through continuous photolithography and dry etching, at least two of the organic light-emitting layers 230 are formed with the organic light-emitting composite according to an embodiment of the present disclosure, so that chemical resistance and etching resistance may be improved, and RGB patterns may be implemented through continuous photolithography and dry etching based on a solution process.

According to an embodiment, the organic light-emitting device according to an embodiment of the present disclosure may further include a first charge auxiliary layer formed between the first electrode 210 and the organic light-emitting layer 230, and the first charge auxiliary layer may include at least one of a hole injection layer, a hole transport layer and an electron blocking layer.

The hole injection layer is a layer that facilitates the injection of holes from the anode of the first electrode 210 to the organic light-emitting layer 230, and has a single layer or a multilayer structure of two or more layers. The hole injection material is a material that can easily receive holes from the first electrode 210 at a low voltage, and the Highest Occupied Molecular Orbital (HOMO) of the hole injection material is preferably between the work function of the material of the first electrode 210 and the HOMO of the surrounding organic layer.

Examples of the hole injection material includes, but are not limited to, metal porphyrine, oligothiophene, arylamine-based organic matter, hexanitrilehexaazatriphenylene-based organic matter, quinacridone-based organic matter, perylene-based organic matter, anthraquinone, and polyaniline- and polycompound-based conductive polymers, etc.

The hole transport layer may play a role in facilitating the transport of holes, and has a single-layer or multilayer structure of two or more layers. As the hole transport material, a material that can receive holes from the first electrode 210 or the hole injection layer and transfer them to the organic light-emitting layer 230 and has high mobility for holes is suitable.

Examples of the hole transport material include, but are not limited to, arylamine-based organic substances, conductive polymers, and block copolymers having both conjugated and non-conjugated portions.

The electron blocking layer is a layer that blocks electrons from reaching the first electrode 210, and may generally be formed under the same conditions as the electron injection layer. Examples of the electron blocking layer include, but are not limited to, HT-B mCP, etc.

According to an embodiment, the organic light-emitting device according to an embodiment of the present disclosure may further include a second charge auxiliary layer formed between the second electrode 250 and the organic light-emitting layer 230, and the second charge auxiliary layer may include at least one of an electron injection layer, an electron transport layer and a hole blocking layer.

The electron injection layer, which is a layer that injects electrons from the second electrode 250, is made of preferably a compound having the ability to transport electrons, having an excellent electron injection effect from the second electrode 250 and an excellent electron injection effect to the organic light-emitting layer 230, capable of preventing the movement of excitons generated in the organic light-emitting layer 230 to a hole injection layer, and having an excellent thin film forming ability. For example, the electron injection layer may be made of fluorenone, anthraquinodimethane, diphenoquinone, thiopyran dioxide, oxazole, oxadiazole, triazole, imidazole, perylenetetracarboxylic acid, preorenylidene methane, anthrone or its derivative, a metal complex compound, a nitrogen-containing 5-membered ring derivative, etc., without being limited thereto.

The electron transport layer, which is a layer that transports electrons to the organic light-emitting layer 230, and as an electron transport material, is made of a material that can well receive electrons from the second electrode 250 and transfer them to the organic light-emitting layer 230, and is suitably made of a material with high mobility for electrons. For example, the electron transport layer may be made of, but is not limited to, an Al complex of 8-hydroxyquinoline, a complex including Alq³, an organic radical compound, a hydroxyflavone-metal complex, etc.

The hole blocking layer, which is a layer that blocks holes from reaching the second electrode 250, may generally be formed under the same conditions as the hole injection layer. For example, the hole blocking layer may be made of, but is not limited to, an oxadiazole derivative, a triazole derivative, a phenanthroline derivative, BCP, an aluminum complex, etc.

### Example 1-1: Phosphorescent Host (CBP-[B(OH)₂]₂ Having Boronic Acid Cross-Linking Functional Group Introduced Thereinto

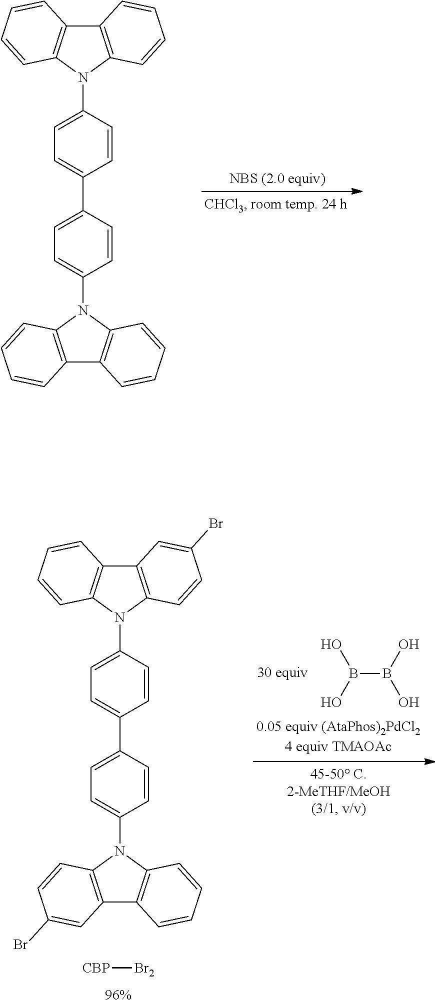

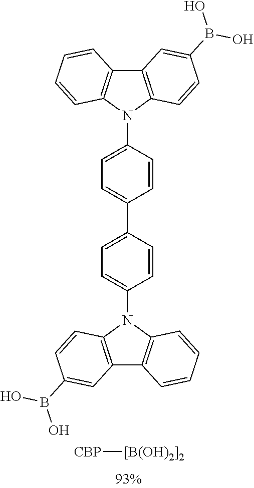

Under an argon atmosphere, 3.65 g (7.54 mmol) of 4,4′-bis(9H—-carbazol-9-yl)biphenyl (CBP) was dissolved in 100 mL of chloroform in a 250 mL round-bottomed flask, and 2.68 g (15.08 mmol) of N-bromosuccinimide (NBS) was added thereto, followed by stirring at room temperature for 24 hours. When the completion of the reaction was confirmed by TLC, the product was diluted in chloroform and the organic layer was washed with saturated brine. The organic layer was dried with anhydrous magnesium sulfate, and magnesium sulfate was filtered off. The residue obtained by concentrating under reduced pressure was separated by silica gel column chromatography (dichloromethane:hexane=1:2) to obtain 4.64 g (7.22 mmol) of a white solid compound (CBP—Br₂)(yield: 96%). ¹H-NMR (300 MHz, CD₂Cl₂) δ=8.30 (dd, J=0.3, 1.5 Hz, 2H), 8.14 (dt, J=0.9, 7.8 Hz, 2H), 7.97 (dd, J=2.1, 6.6 Hz, 2H), 7.97 (dd, J=1.8, 6.6 Hz, 2H), 7.57-7.49 (m, 6H), 7.41 (dd, J=0.3, 8.7 Hz, 2H), 7.36-7.31 (m, 2H) ppm.

Under an argon atmosphere, 642 mg (1.0 mmol) of CBP—Br₂, 2.69 g (30 mmol) of tetrahydroxydiborane (BBA), 532 mg (4.0 mmol) of tetramethylammonium acetate (TMAOAc), and 35 mg (0.05 mmol) of bis[di-tert-butyl (4-dimethylaminophenyl)phosphine]dichloropalladium (II)((AtaPho)₂PdCl₂) were dissolved in a mixed solution containing 45 mL of 2-methyltetrahydrofuran and 15 mL of methanol in a 100 mL round-bottom flask, followed by stirring for 3 days while maintaining the reaction temperature at 45 to 50° C. When the completion of the reaction was confirmed by TLC, the residue obtained by concentrating the product under reduced pressure was separated by silica gel column chromatography (dichloromethane:methanol=9:1) to obtain 530 mg (0.93 mmol) of a pale yellow compound (CBP-[B(OH)₂]₂)(yield: 93%). ¹H-NMR (300 MHz, MeOD-d₄) δ=8.64 (s, ¹H), 8.50 (s, ¹H), 8.21 (d, J=8.1 Hz, 2H), 8.07 (dd, J=1.8, 6.6 Hz, 4H), 7.87 (d, J=8.1 Hz, 2H), 7.74 (d, J=8.4 Hz, 2H), 7.50-7041 (m, 6H), 7.31 (dt, J=0.5, 8.1 Hz, 2H) ppm.

### Example 1-2: Phosphorescent Dopant (Ir[Pyp-B(OH)₂]₃ Having Boronic Acid Cross-Linking Functional Group Introduced Thereinto

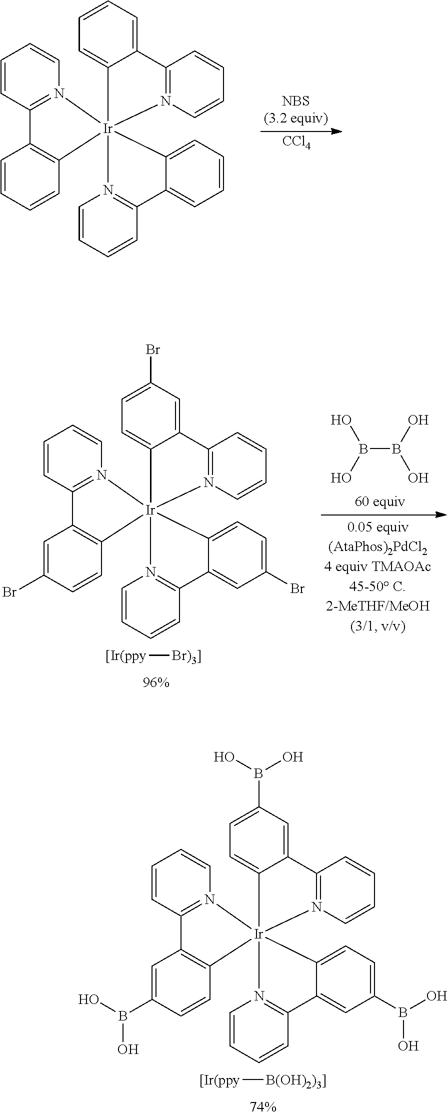

Under an argon atmosphere, 120 mL of carbon tetrachloride was dissolved in 200 mg (0.31 mmol) of tris(2-phenylpyridinato-C²,N)iridium (III) (fac-Ir(ppy)₃) in a 250 mL round-bottomed flask, and 174 mg (0.98 mmol) of N-bromosuccinimide (NBS) was added thereto, following by refluxing and stirring for 48 hours in an 85° C. oil bath. When the completion of the reaction was confirmed by TLC, the product was cooled to room temperature, and then concentrated under reduced pressure. The concentrated residue was diluted with dichloromethane, and the organic layer was washed with saturated brine. The organic layer was dried using anhydrous magnesium sulfate, and then magnesium sulfate was filtered off. A residue obtained by concentrating under reduced pressure was separated by silica gel column chromatography (dichloromethane:hexane=2:1) to obtain 261 mg (0.293 mmol) of a yellow solid compound (Ir(ppy-Br)₃)(yield: 96%). ¹H-NMR (300 MHz, CD₂Cl₂) δ=7.89 (d, J=31.5 Hz, 3H), 7.75 (d, J=9.0 Hz, 3H), 7.71 (dt, J=1.5, 6.0 Hz, 3H), 7.53 (dt, J=0.9, 4.5 Hz, 3H) 6.98 (dt, J=1.2, 4.5 Hz, 3H), 6.89 (dt, J=2.1, 8.1 Hz, 3H), 6.64 (d, J=8.1 Hz, 3H) ppm.

Under an argon atmosphere, 89 mg (0.1 mmol) of Ir(ppy-Br)₃, 540 mg (6.0 mmol) of tetrahydroxydiborane (BBA), 80 mg (0.6 mmol) of tetramethylammonium acetate (TMAOAc), and 8 mg (0.01 mmol) of bis[di-tert-butyl (4-dimethylaminophenyl)phosphine]dichloropalladium (II) ((AtaPho)₂PdCl₂) were dissolved in a mixed solution containing 15 mL of 2-methyltetrahydrofuran and 5 mL of methanol in a 50 mL round-bottom flask and stirred for 3 days while maintaining the reaction temperature at 45 to 50° C. When the completion of the reaction was confirmed by TLC, the product was concentrated under reduced pressure, and the obtained residue was separated by silica gel column chromatography (dichloromethane:methanol=9:1), thereby obtaining 58 mg (0.074 mmol) of a dark yellow solid compound (Ir[pyp-B(OH)₂]₃)(yield: 74%). ¹H-NMR (300 MHz, Acetone-d₆) δ=8.31 (brs, OH), 8.13 (d, J=8.4 Hz, 3H), 7.78 (dt, J=1.5, 4.8 Hz, 3H), 7.65 (dt, J=0.9, 4.8 Hz, 3H), 7.25 (dd, J=1.2, 7.5 Hz, 3H), 7.06 (dt, J=1.2, 4.3 Hz, 3H), 6.90 (d, J=7.5 Hz, 3H), 6.83 (s, 3H) ppm.

### Example 2-1: Phosphorescent Host (CBP-MOVB₂) Having Vinyl Cross-Linking Functional Group Introduced Thereinto

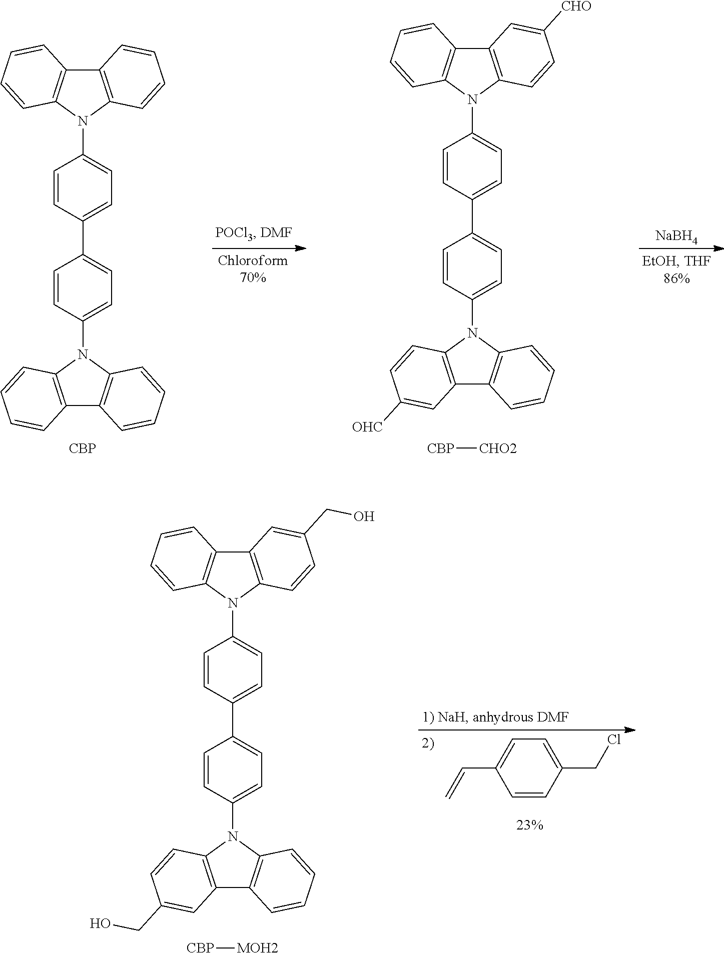

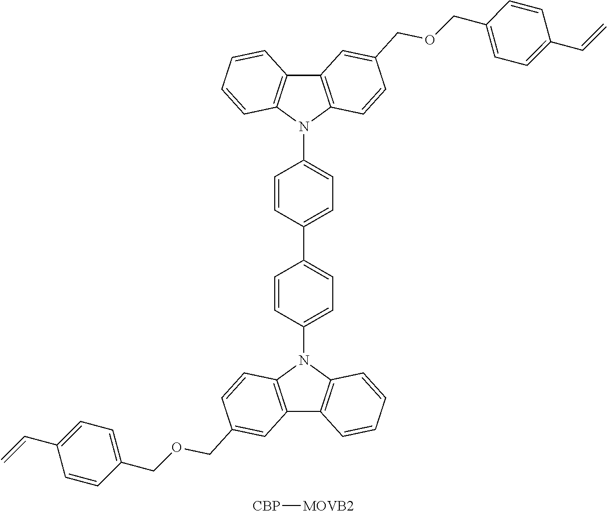 [SMILES: C=Cc1ccc(COCc2ccc3c(c2)c2ccccc2n3-c2ccc(-c3ccc(-n4c5ccccc5c5cc(COCc6ccc(C=C)cc6)ccc54)cc3)cc2)cc1 ; "CBP" ; "MOVB2"]

Under an argon atmosphere, 2000 mg (4.110 mmol) of 4,4′-bis(9H—-carbazol-9-yl)biphenyl (CBP) was dissolved in 20.6 mL of chloroform in a 250 mL round-bottom flask, 6.68 mL (86.61 mmol) of dimethylformamide (DMF) was added thereto, and 9.61 mL (102.8 mmol) of chlorophosphoric acid (POCl₃) diluted in 41.1 mL of chloroform was added thereto at 0° C., followed by stirring at 80° C. for 70 hours. When the completion of the reaction was confirmed by TLC, the reaction was terminated with an aqueous sodium bicarbonate solution (NaHCO₃ (aq)), and extraction was performed three times with dichloromethane (DCM). Next, the organic solvent layer was concentrated under reduced pressure, and then precipitated with n-hexane (n-hexane), and then filtered through a filter paper, thereby obtaining a white solid compound (CBP—CHO2 1535 mg (2.667 mmol))(yield: 70%). 1H-NMR (400 MHZ, Chloroform-d) δ 10.16 (s, 2H), 8.71 (s, 2H), 8.25 (d, J=7.8 Hz, 2H), 8.01 (d, J=8.9 Hz, 2H), 7.97 (d, J=7.9 Hz, 6H), 7.73 (d, J=7.6 Hz, 4H), 7.56 (d, J=8.7 Hz, 2H), 7.52 (s, 4H), 7.43 (d, J=7.1 Hz, 2H) ppm.

Under an argon atmosphere, 1000 mg (1.850 mmol) of CBP—CHO2 was dissolved in a mixed solution containing 71 mL of tetrahydrofuran (THF) and 47 mL of ethanol (EtOH) in a 250 mL round-bottom flask, and then 167.9 mg (4.436 mmol) of sodium borohydride (NaBH₄) was slowly added thereto and stirred at room temperature for 15 hours. When the completion of the reaction was confirmed by TLC, the product was filtered through a vacuum filtration device and washed three times with water to obtain a white solid compound (CBP-MOH2 863 mg (1.584 mmol)(yield: 86%). ¹H-NMR (400 MHZ, Chloroform-d) δ 8.18 (d, J=9.2 Hz, 4H), 7.93 (d, J=7.7 Hz, 4H), 7.71 (d, J=7.7 Hz, 4H), 7.55-7.42 (m, 8H), 7.33 (t, J=7.4 Hz, 2H), 4.91 (d, J=5.7 Hz, 4H) ppm.

Under an argon atmosphere, 1000 mg (1.836 mmol) of CBP-MOH2 was dissolved in 30 mL of anhydrous dimethylformamide (anhydrous DMF) in a 250 mL round-bottom flask and stirred for 1 hour, followed by slowly adding 220.5 mg (5.581 mmol) of sodium hydride (NaH 60% in oil) thereto and stirring for 3 hours at room temperature. Next, 0.8 mL (5.581 mmol) of 4-vinylbenzyl chloride was slowly added thereto at 0° C., and then stirred at room temperature for 30 hours. When the completion of the reaction was confirmed by TLC, water was slowly added to the product at 0° C. to terminate the reaction. Next, extraction was performed three times using dichloromethane (DCM), and then a residue obtained by concentrating the organic layer under reduced pressure was separated by silica gel column chromatography (dichloromethane) to obtain 330 mg (0.4247 mmol) of a white solid compound (CBP-MOVB₂)(yield: 23%). ¹H-NMR (400 MHZ, Chloroform-d) δ 8.17 (d, J=6.5 Hz, 4H), 7.93 (d, J=8.7 Hz, 4H), 7.71 (d, J=7.7 Hz, 4H), 7.58-7.29 (m, 18H), 6.74 (dd, J=17.6, 10.9 Hz, 2H), 5.77 (d, J=17.5 Hz, 2H), 5.25 (d, J=10.8 Hz, 2H), 4.77 (s, 4H), 4.62 (s, 4H) ppm.

### Example 2-2: Phosphorescent Dopant (Ir(Ppy)₃-MOVB₃) Having Vinyl Cross-Linking Functional Group Introduced Thereinto

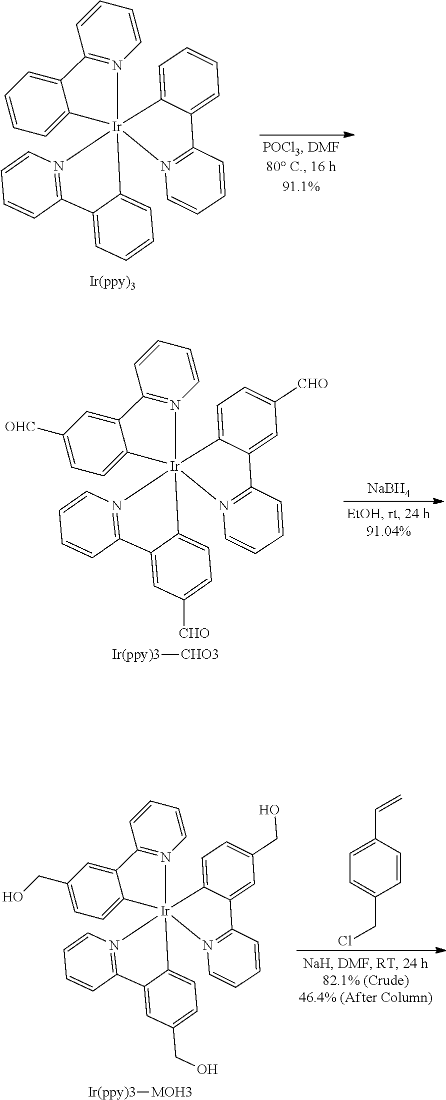

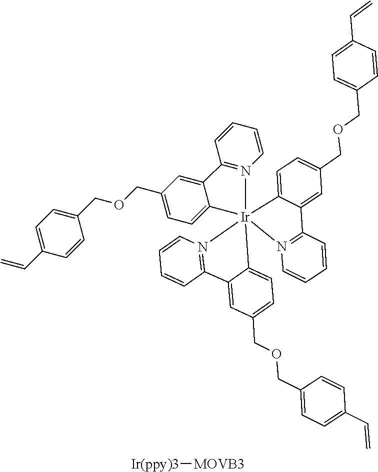

Under an argon atmosphere, 1.5 mL of dimethylformamide (DMF) was fed into a 10 mL round-bottom flask, and 0.3 mL of chlorophosphoric acid (POCl₃) was added thereto dropwise, followed by stirring at room temperature for 1 hour. Next, 50 mg (0.076 mmol) of tris(2-phenylpyridinato-C²,N)iridium (III) (fac-Ir(ppy)₃) was added thereto, followed by stirring at 80° C. for 16 hours. When the completion of the reaction was confirmed by TLC, the reaction was terminated by adding 4.5 mL of 1 M sodium hydroxide at 0° C. Next, the product was stirred at room temperature for 12 hours, and then filtered through a filter, and then washed with water three times, thereby obtaining 53 mg (0.07636 mmol) of a yellow solid compound (Ir(ppy)₃-CHO3)(yield: 95%). ¹H-NMR (400 MHZ, Chloroform-d): δ=9.88 (s, 3H), 8.19 (s, 3H), 8.1 (d, 3H), 7.76 (t, 3H), 7.52 (d, 3H), 7.26 (d, 3H), 7.04 (t, 3H), 6.99 (d, 3H) ppm.

Under an argon atmosphere, 210 mg (0.284 mmol) of Ir(ppy)₃-CHO3 was dissolved in 30.0 mL of ethanol (EtOH) in a 100 mL round-bottom flask, and then 253 mg (6.680 mmol) of sodium borohydride (NaBH₄) was added thereto, followed by stirring at room temperature for 12 hours. When the completion of the reaction was confirmed by TLC, the product was filtered through a vacuum filtration device and washed with water three times, followed by obtaining 193 mg (0.2591 mmol) of a yellow solid compound (Ir(ppy)₃-MOH3 (yield: 95%). ¹H-NMR (400 MHZ, DMSO-d₆): δ=8.05 (d, 3H), 7.76 (t, 3H), 7.66 (s, 3H), 7.43 (d, 3H), 7.07 (t, 3H), 6.63 (q, 6H), 4.83 (bs, 3H), 4.31 (bs, 6H) ppm.

Under an argon atmosphere, 95 mg (0.128 mmol) of Ir(ppy)₃-MOH3 was dissolved in 5.0 mL of anhydrous dimethylformamide (anhydrous DMF) in a 25 mL round-bottom flask and stirred for 1 hour, followed by slowly adding 47 mg (0.284 mmol) of sodium hydride (NaH 60% in oil) thereto and stirring at room temperature for 3 hours. Next, 0.087 mL (0.638 mmol) of 4-vinylbenzyl chloride dissolved in 2.0 mL of anhydrous tetrahydrofuran (anhydrous THF) was slowly added thereto at 0° C., followed by stirring at room temperature for 24 hours. When the completion of the reaction was confirmed by TLC, the reaction was terminated by slowly adding ice to the product at 0° C. Next, extraction was performed three times using dichloromethane (DCM), and then sodium sulfate was added to the organic layer and stirred for 1 hour. Next, a residue obtained by concentrating under reduced pressure was separated through silica gel column chromatography (dichloromethane:hexane=10:1) to obtain 65 mg (0.05945 mmol) of a yellow solid compound (Ir(ppy)₃-MOVB₃)(yield: 46%). ¹H-NMR (400 MHz, Chloroform-d): δ=7.89 (d, 3H), 7.64 (s, 3H), 7.58 (t, 3H), 7.51 (d, 3H), 7.38 (d, 6H), 7.32 (d, 6H), 6.88-6.80 (m, 9H), 6.71 (dd, 3H), 6.73 (d, 3H), 5.23 (d, 3H), 4.54 (s, 6H), 4.44 (s, 6H) ppm.

### Example 3: Organic Light-Emitting Composite (CBP-MOVB₂: Ir(Ppy)₃-MOVB₃: 1,8-bis(trichlorosilyl)octane)

In a 4 ml vial, CBP-MOVB₂ (curable phosphorescent host) and Ir(ppy)₃-MOVB₃ (curable phosphorescent dopant) were dissolved in a chloroform solvent at a dopant concentration of 93% by weight and a host concentration of 7% by weight and stirred for 3 hours in a nitrogen environment to prepare a solution. 1.9% by weight to 7.4% by weight of 1,8-bis(trichlorosilyl)octane (organic silica precursor) relative to the weight of the host was added to the prepared solution, followed by stirring in a nitrogen environment for 1 hour. The stirred solution was applied on a substrate, and then an organic luminant thin film was formed by a spin coating method (2,000 rpm, 60 sec). The formed thin film was heat-treated at 180° C. for 3 hours in a nitrogen environment to proceed a crosslinking reaction between vinyl functional groups and a silicone network formation reaction between organic silica precursors. Finally, a silicone (—Si—O—Si—)-integrated IPN-type organic light-emitting composite material was developed.

### Example 4: Organic Light-Emitting Device

PEDOT:PSS (A14083) was applied to the entire surface of an ITO (anode) substrate, and then a thin film was manufactured by a spin coating method (4,000 rpm, 60 sec), and then heat treatment was performed at 120° C. for 1 hour, thereby forming a charge injection layer.

A thin film was manufactured by applying a cross-linked small-molecule semiconductor material, QUPD [N4,N4′-Bis (4-(6-((3-ethyloxetan-3-yl)methoxy)hexyloxy)phenyl)-N4,N4′-bis(4-methoxyphenyl)biphenyl-4,4′-diamine], on the charge injection layer in a nitrogen environment by a spin coating method (2,000 rpm, 60 sec), and then a cross-linked charge transport layer was formed through heat treatment at 180° C. for 3 hours. The entire surface of the formed charge transport layer was coated with a solution in which the host (CBP-MOVB₂)-dopant (Ir(ppy)₃-MOVB₃) having the vinyl cross-linking functional group introduced thereto and the organic silica precursor (1,8-bis(trichlorosilyl)octane) were mixed (the host: 93% by weight, the dopant: 7% by weight, and the organic silica precursor: 1.9% by weight to 7.4% by weight relative to the weight of the host), thereby manufacturing a thin film by a spin coating method (2,000 rpm, 60 sec). Next, a silicone (—Si—O—Si—)-integrated IPN-type organic light-emitting composite was formed by heat-treating at 180° C. for 30 minutes. On the formed organic light-emitting layer, the electron transport layer, TPBi(2,2′,2″-(1,3,5-Benzinetriyl)-tris (1-phenyl-1-H-benzimidazole), and the cathode, LiF:Al/Al, were deposited. Finally, an organic light-emitting diode device was manufactured.

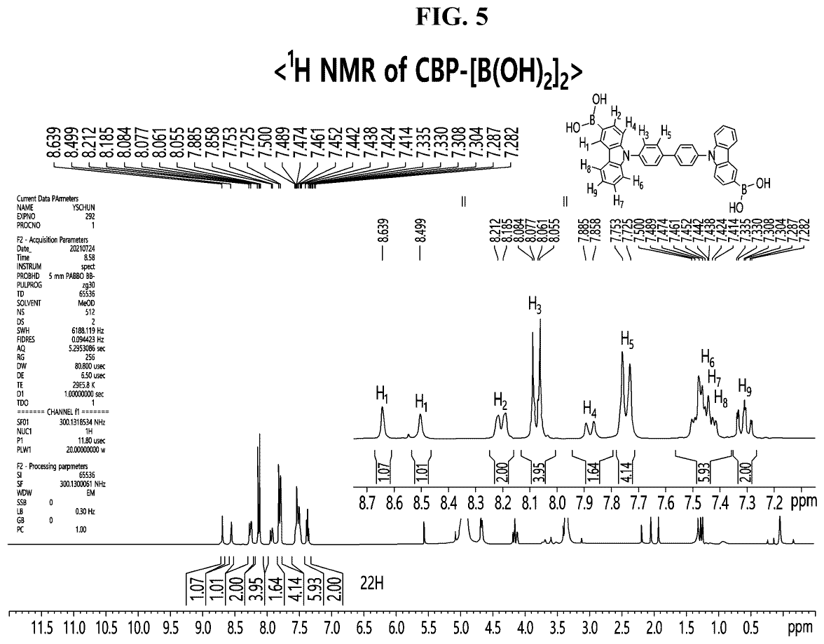

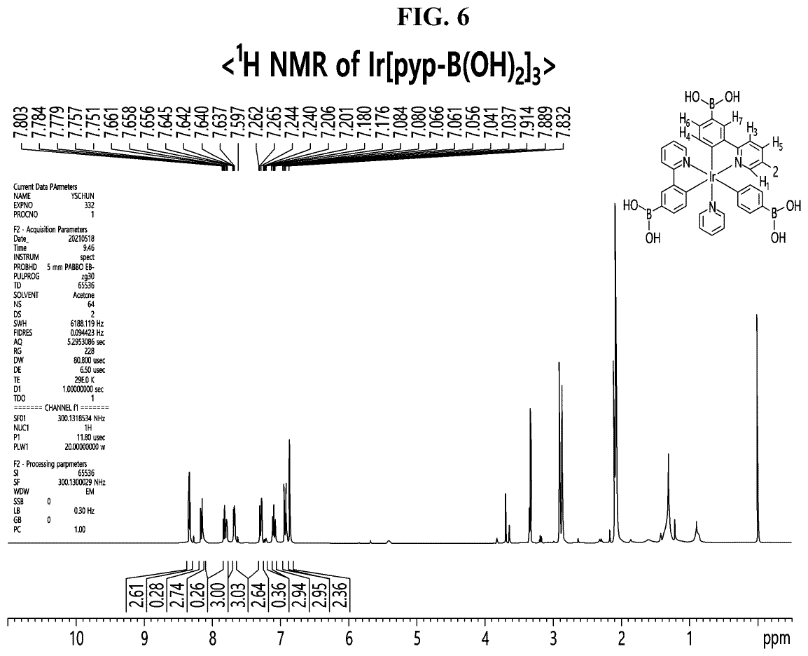

FIG. 5 is a graph illustrating the result of ¹HNMR analysis of the phosphorescent host (CBP-[B(OH)₂]₂, into which the boronic acid cross-linking functional group has been introduced, according to Example 1-1, and FIG. 6 is a graph illustrating the result of ¹HNMR analysis of the phosphorescent dopant (Ir[pyp-B(OH)₂]₃, into which the boronic acid cross-linking functional group has been introduced, according to Example 1-2.

Referring to FIGS. 5 and 6, it can be confirmed through 1H NMR analysis that both the phosphorescent host (CBP-[B(OH)₂]₂ having the boronic acid cross-linking functional group introduced thereinto and phosphorescent dopant (Ir[pyp-B(OH)₂]₃ having the boronic acid cross-linking functional group introduced thereinto have been synthesized in a high yield (purity: 99% or more) of 96% or more.

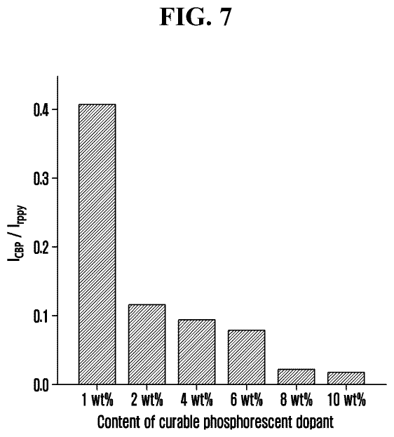

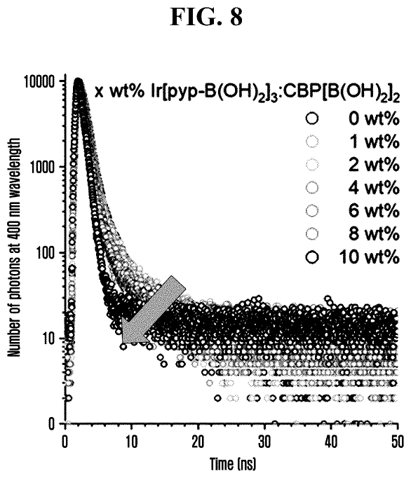

FIG. 7 is a graph illustrating the luminescence intensity of the phosphorescent host (CBP-[B(OH)₂]₂, into which the boronic acid cross-linking functional group has been introduced, dependent upon the content of the phosphorescent dopant (Ir[pyp-B(OH)₂]₃ into which the boronic acid cross-linking functional group has been introduced, and FIG. 8 is a graph illustrating the charge lifespan of the phosphorescent host (CBP-[B(OH)₂]₂, into which the boronic acid cross-linking functional group has been introduced, dependent upon the content of the phosphorescent dopant (Ir[pyp-B(OH)₂]₃ into which the boronic acid cross-linking functional group has been introduced.

Referring to FIGS. 7 and 8, it can be confirmed that the luminescence intensity and charge lifespan of the phosphorescent host (CBP-[B(OH)₂]₂ into which the boronic acid cross-linking functional group has been introduced are decreased as the content of the phosphorescent dopant (Ir[pyp-B(OH)₂]₃ into which the boronic acid cross-linking functional group has been introduced increases.

Accordingly, it can be seen that energy transfer between the host and the dopant is efficiently induced even though the boronic acid cross-linking functional group has been introduced into the phosphorescent host and the phosphorescent dopant.

Accordingly, the energy transfer mechanism between the host material and dopant material into which the boronic acid cross-linking functional group has been introduced may be elucidated.

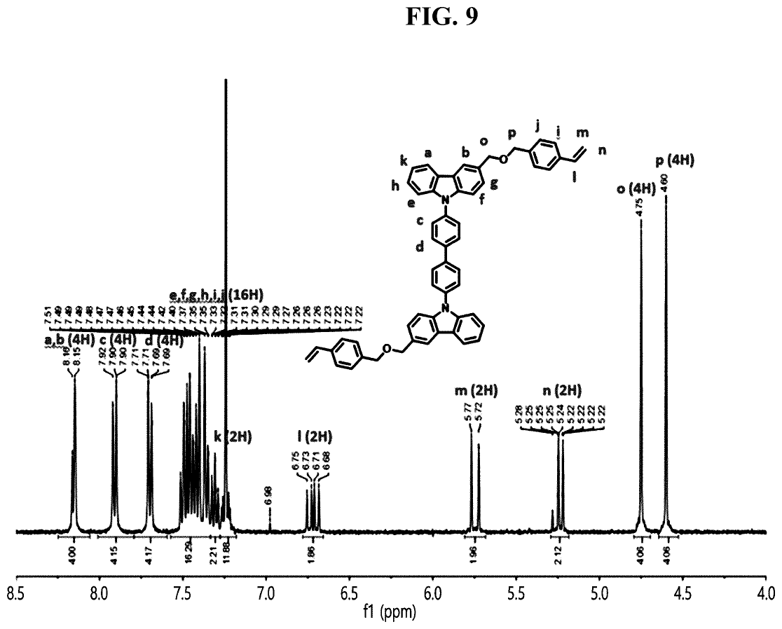

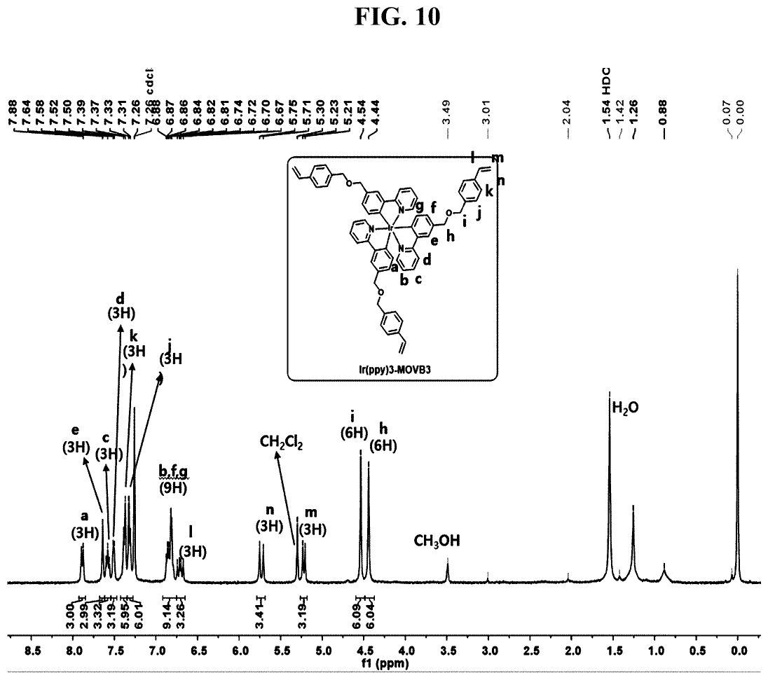

FIG. 9 is a graph illustrating the result of ¹HNMR analysis of the phosphorescent host (CBP-MOVB₂), into which the vinyl cross-linking functional group has been introduced, and FIG. 10 is a graph illustrating the result of ¹HNMR analysis of the phosphorescent dopant (Ir(ppy)₃-MOVB₃) into which the vinyl cross-linking functional group has been introduced.

Referring to FIGS. 9 and 10, it can be seen from ¹H NMR analysis that both the phosphorescent host (CBP-MOVB₂) into which the vinyl cross-linking functional group has been introduced and the phosphorescent dopant (Ir(ppy)₃-MOVB₃) into which the vinyl cross-linking functional group has been introduced have been synthesized in a high yield (purity 99% or more) of 96% or more.

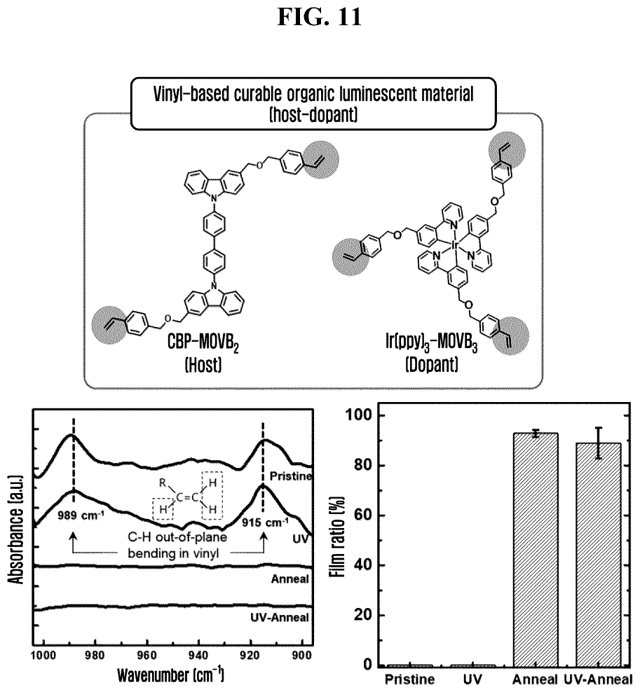

FIG. 11 is a graph illustrating the FT-IR and thin film chemical resistance analysis results for the crosslinking reaction of the curable phosphorescent host (CBP-MOVB₂), into which the vinyl cross-linking functional group has been introduced, according to Example 2-1 and the phosphorescent dopant (Ir(ppy)₃-MOVB₃), into which the vinyl cross-linking functional group has been introduced, according to Example 2-2.

Referring to FIG. 11, it can be seen from FT-IR that the vinyl cross-linking functional group is effectively crosslinked by heat treatment. In addition, it can be seen that the chemical (solvent (chloroform) exposure) resistance of the curable organic light-emitting layer manufactured based on the curable phosphorescent host (CBP-MOVB₂), into which the vinyl cross-linking functional group has been introduced, according to Example 2-1: the phosphorescent dopant (Ir(ppy)₃-MOVB₃), into which the vinyl cross-linking functional group has been introduced, according to Example 2-2 is improved.

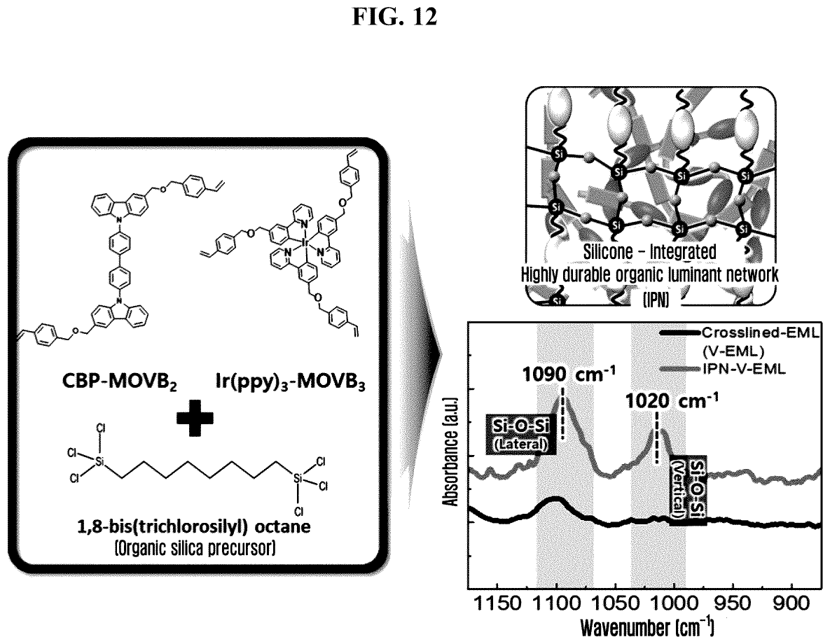

FIG. 12 illustrates a schematic diagram of the organic light-emitting composite (Example 3) having the silicone (—Si—O—Si—)-integrated IPN including the curable phosphorescent host (CBP-MOVB₂), into which the vinyl cross-linking functional group has been introduced, according to Example 2-1, the phosphorescent dopant (Ir(ppy)₃-MOVB₃), into which the vinyl cross-linking functional group has been introduced, according to Example 2-2 and an organic silica precursor (1,8-bis(trichlorosilyl)octane), and the FT-IR result of a silicone (—Si—O—Si—) network formation reaction.

Referring to FIG. 12, it can be seen from FT-IR analysis that when the organic light-emitting composite forms a network having high durability by introducing the organic silica precursor into the curable phosphorescent host (CBP-MOVB₂), into which the vinyl cross-linking functional group has been introduced, according to Example 2-1: the phosphorescent dopant (Ir(ppy)₃-MOVB₃), into which the vinyl cross-linking functional group has been introduced, according to Example 2-2, the silicone (—Si—O—Si—) network is effectively formed in the curable organic light-emitting layer thin film.

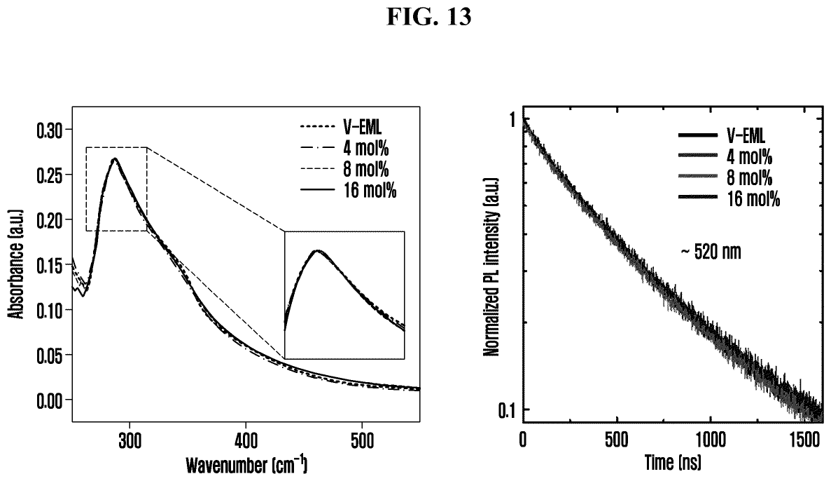

FIG. 13 illustrates the optoelectronic property analysis results, dependent upon the content of the organic silica precursor, of the organic light-emitting composite according to FIG. 12.

FIG. 13 shows the optoelectronic properties of the highly durable organic light-emitting composite network dependent upon the content of the organic silica precursor.

Referring to FIG. 13, it can be seen that the optoelectronic properties of the organic light-emitting composite and the energy transfer behavior between the host and dopant are not changed despite the introduction of the silicone (—Si—O—Si—) network.

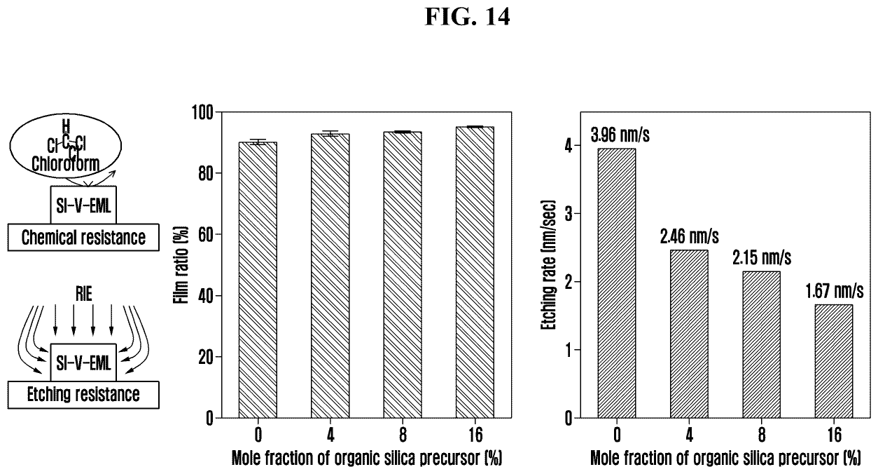

FIG. 14 illustrates chemical resistance and etching resistance evaluation results of the organic light-emitting thin film including the organic light-emitting composite according to FIG. 12.

FIG. 14 shows durability (chemical resistance and etching resistance) evaluation results of the organic light-emitting composite network having high durability.

Referring to FIG. 14, it can be seen that chemical resistance and etching resistance (about 40% reduction) may be simultaneously secured even when only about 4 mol % of an organic silica precursor is added to the curable organic luminant.

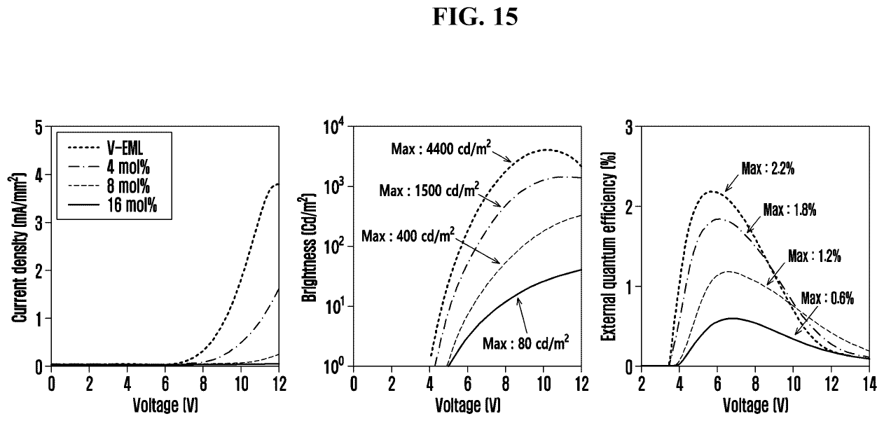

FIG. 15 illustrates analysis results of the luminescence characteristics of an OLED device (Example 4) using the organic light-emitting composite according to FIG. 12 as a light-emitting layer.

FIG. 15 shows analysis results of an organic light-emitting device according to an embodiment of the present disclosure including an organic light-emitting composite as an organic light-emitting layer.

Referring to FIG. 15, it can be seen that, when introducing 4 mol % of an organic silica precursor, EQE decreases by about 18% compared to a parent device (comparative example) excluding the organic silica precursor, but the OLED device operates well without any problems.

Meanwhile, embodiments of the present disclosure disclosed in the present specification and drawings are only provided to aid in understanding of the present disclosure and the present disclosure is not limited to the embodiments. It will be apparent to those skilled in the art that various modifications can be made to the above-described exemplary embodiments of the present disclosure without departing from the spirit and scope of the disclosure.

1. An organic light-emitting composite, comprising:
a curable phosphorescent host;
a curable phosphorescent dopant; and
an organic silica precursor forming a silicone (—Si—O—Si—) network together with the curable phosphorescent host and the curable phosphorescent dopant,
wherein the curable phosphorescent host and the curable phosphorescent dopant comprise a cross-linking functional group.

2. The organic light-emitting composite according to claim 1, wherein the silicone (—Si—O—Si—) network is a silicone (—Si—O—Si—)-integrated Single Phase Network (SPN), and
the silicone (—Si—O—Si—)-integrated SPN is formed by a simultaneous crosslinking reaction among the curable phosphorescent host, the curable phosphorescent dopant and the organic silica precursor.

3. The organic light-emitting composite according to claim 1, wherein the silicone (—Si—O—Si—) network is a silicone (—Si—O—Si—)-integrated Interpenetrating Polymer Network (IPN), and
the silicone (—Si—O—Si—)-integrated IPN is formed by a simultaneous crosslinking reaction between the curable phosphorescent host and the curable phosphorescent dopant and a selective crosslinking reaction between the organic silica precursor.

4. The organic light-emitting composite according to claim 1, wherein the cross-linking functional group comprises at least one of a vinyl group, a vinyl group derivative, an oxetane group, a boronic acid group, trifluoro vinyl ether, benzocyclobutene and epoxide.

5. The organic light-emitting composite according to claim 4, wherein the cross-linking functional group comprises a functional group represented by one of Formulas 4 to 9 below: 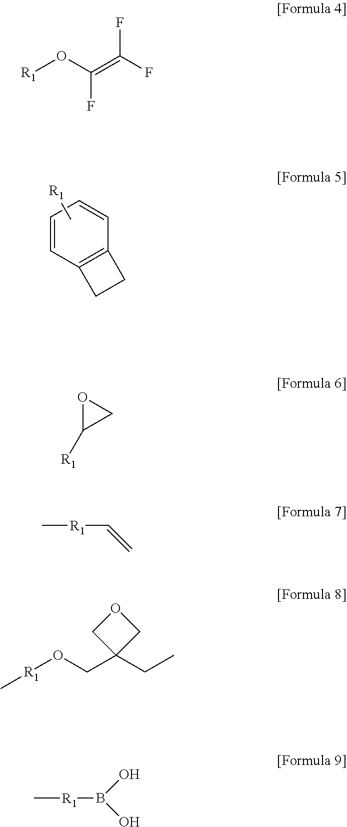
wherein, in Formulas 4 to 9, R₁ each independently comprises one of a hydrogen, a heavy hydrogen, a cyano group, a halogen group, an amino group, a thiol group, a hydroxy group, a nitro group, a carbonyl group, an ether group, a silane group, a siloxane group, a substituted or unsubstituted alkyl group having 1 to 20 carbon atoms, a substituted or unsubstituted cycloalkyl group having 3 to 20 carbon atoms, a substituted or unsubstituted alkenyl group having 2 to 20 carbon atoms, a substituted or unsubstituted alkynyl group having 2 to 20 carbon atoms, a halogenated alkyl group having 1 to 20 carbon atoms, a substituted or unsubstituted fluorenyl group, a substituted or unsubstituted aryl group having 6 to 30 carbon atoms, a substituted or unsubstituted aryloxy group having 6 to 30 carbon atoms, a substituted or unsubstituted heteroaryl group having 2 to 30 carbon atoms, a substituted or unsubstituted alkoxy group having 1 to 20 carbon atoms, a substituted or unsubstituted alkylsilyl group having 1 to 20 carbon atoms, a substituted or unsubstituted arylsilyl group having 6 to 30 carbon atoms, a substituted or unsubstituted arylalkyl group having 7 to 30 carbon atoms, a substituted or unsubstituted alkenyloxyl group having 2 to 30 carbon atoms, a substituted or unsubstituted aryl group having 8 to 30 carbon atoms alkenylaryl group, a substituted or unsubstituted arylalkoxy group having 7 to 30 carbon atoms, a substituted or unsubstituted arylalkenyl group having 8 to 30 carbon atoms and a substituted or unsubstituted alkoxycarbonyl group having 2 to 20 carbon atoms.

6. The organic light-emitting composite according to claim 1, wherein the curable phosphorescent dopant is a metal complex compound to which the cross-linking functional group has been bonded, and
the metal complex compound comprises at least one metal of iridium (Ir), platinum (Pt), osmium (Os), gold (Au), titanium (Ti), zirconium (Zr), hafnium (Hf), euroform (Eu), terbium (Tb), palladium (Pd) and thallium (Tm).

7. The organic light-emitting composite according to claim 6, wherein the curable phosphorescent dopant comprises a compound represented by one of Formulas 10 and 11 below: 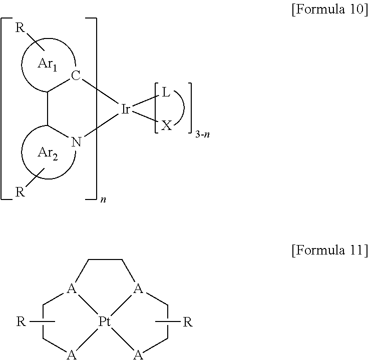
wherein, in Formulas 10 and 11, n is 2 or 3, Ar₁ and Ar₂ are each at least one of a negatively charged and neutrally independently substituted or unsubstituted aryl group having 6 to 30 carbon atoms, a substituted or unsubstituted fluorenyl group and a substituted or unsubstituted heteroaryl group having 2 to 30 carbon atoms, L-X is a negatively charged di-coordinate ligand, R is a cross-linking functional group, and A each independently comprises at least one of a substituted or unsubstituted aryl group having 6 to 30 carbon atoms, a substituted or unsubstituted fluorenyl group and a substituted or unsubstituted heteroaryl group having 2 to 30 carbon atoms.

8. The organic light-emitting composite according to claim 7, wherein luminescence intensity and charge lifespan of the organic light-emitting composite are controlled depending upon a content of the curable phosphorescent dopant.

9. The organic light-emitting composite according to claim 8, wherein a content of the curable phosphorescent dopant is 0.5% by weight to 20% by weight based on the organic light-emitting composite.

10. The organic light-emitting composite according to claim 1, wherein the curable phosphorescent host is a host compound to which the cross-linking functional group has been bonded, and
the host compound comprises at least one of a carbazole-based compound, an anthracene-based compound, a fluorene-based compound, a triarylamine-based compound, a dibenzofuran-based compound, a dibenzothiophene-based compound, a dibenzosilole-based compound, a triazine-based compound, a triazole-based compound, an imidazole-based compound, an oxazine-based compound, an arylamine-based compound, a hydrazone-based compound, a stilbene-based compound, a starburst-based compound, an oxadiazole-based compound, a phosphine oxide-based compound, a bipyrimidine-based compound, a silane-based compound and a carboline-based compound.

11. The organic light-emitting composite according to claim 10, wherein the curable phosphorescent host comprises a compound represented by one of Formulas 1 to 3 below: 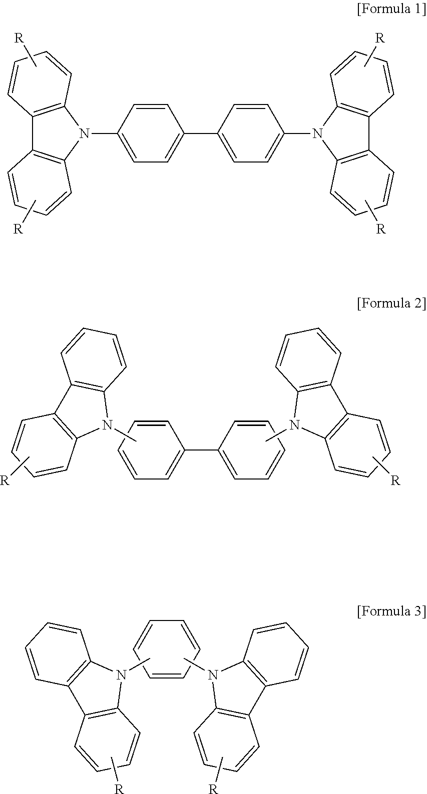
wherein, in Formulas 1 to 3, R is a cross-linking functional group.

12. The organic light-emitting composite according to claim 1, wherein the organic silica precursor comprises a compound represented by one of Formulas 12 to 22 below: 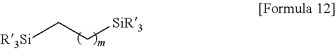
wherein, in Formula 12, R′ comprises one to three halogen elements or one to three alkoxy (—O—(CH₂)ₓ—CH₃, where X is an integer of 0 to 8.), and m is an integer of 0 to 20 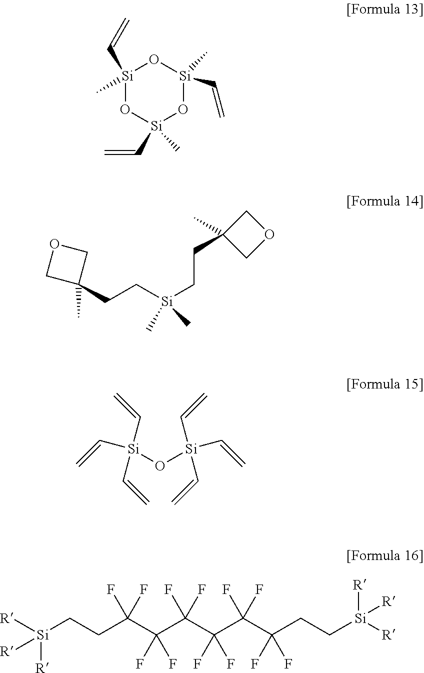
wherein, in Formula 16, R′ comprises one to three halogen elements or one to three alkoxy (—O—(CH₂)ₓ—CH₃, where X is an integer of 0 to 8

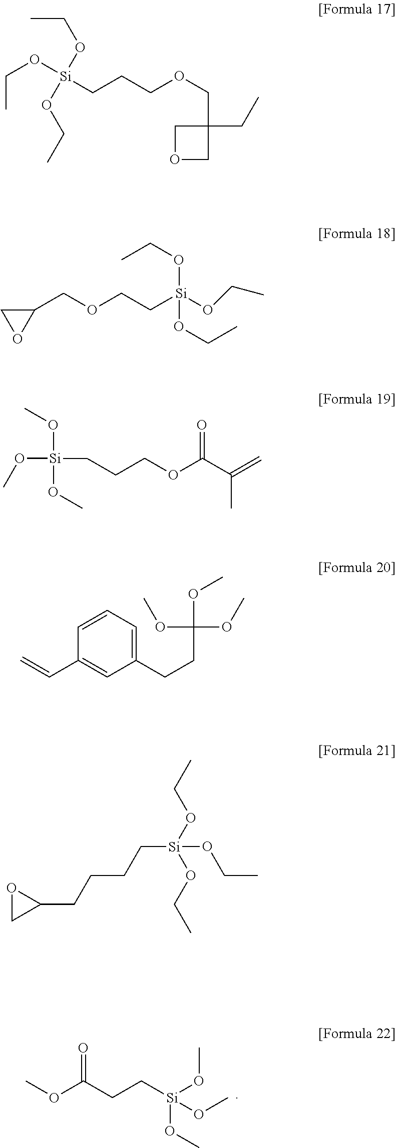

13. A patterning method for an organic light-emitting thin film, the patterning method comprising:
forming an organic light-emitting thin film comprising an organic light-emitting composite on a substrate;
forming a photoresist on the organic light-emitting thin film;
patterning the photoresist to form a photoresist pattern;
dry-etching the organic light-emitting thin film using the photoresist pattern as an etching mask to form an organic light-emitting pattern; and
removing the photoresist pattern.

14. The patterning method according to claim 13, wherein the organic light-emitting composite comprises:
a curable phosphorescent host;
a curable phosphorescent dopant; and
an organic silica precursor forming a silicone (—Si—O—Si—) network together with the curable phosphorescent host and the curable phosphorescent dopant,
wherein the curable phosphorescent host and the curable phosphorescent dopant comprise a cross-linking functional group,
wherein the silicone (—Si—O—Si—) network is one of a silicone (—Si—O—Si—)-integrated Single Phase Network (SPN) and a silicone (—Si—O—Si—)-integrated Interpenetrating Polymer Network (IPN).

15. The patterning method according to claim 14, wherein, in the dry-etching, the organic light-emitting thin film is formed as a non-volatile blocking layer on a side surface of the organic light-emitting pattern by the silicone (—Si—O—Si—) network of the organic light-emitting composite.

16. The patterning method according to claim 15,
wherein the non-volatile blocking layer comprises at least one of SixOy and SixOyFz, and
wherein x, y and z are an integer of 1 to 4.

17. The patterning method according to claim 13, wherein the organic light-emitting pattern has a size of 10 nm to 1000 μm.

18. An organic light-emitting device, comprising:
a first electrode;
a second electrode; and
an organic light-emitting layer formed between the first electrode and the second electrode and comprising an organic light-emitting composite,
wherein the organic light-emitting composite comprises:
a curable phosphorescent host;
a curable phosphorescent dopant; and
an organic silica precursor forming a silicone (—Si—O—Si—) network together with the curable phosphorescent host and the curable phosphorescent dopant,
wherein the curable phosphorescent host and the curable phosphorescent dopant comprise a cross-linking functional group.

19. The organic light-emitting device according to claim 18, wherein the organic light-emitting layer comprises at least one of a red organic light-emitting pattern, a green organic light-emitting pattern and a blue organic light-emitting pattern.

20. (canceled)

21. The organic light-emitting device according to claim 18, wherein the organic light-emitting composite comprises:
80% by weight to 99.5% by weight of the curable phosphorescent host, and
0.5% by weight to 20% by weight of the curable phosphorescent dopant,
wherein the organic light-emitting composite comprises 1.9% by weight to 7.4% by weight of the organic silica precursor relative to a weight of the curable phosphorescent host.

22. (canceled)
